(19) United States
(12) Patent Application Publication
(10) Pub. No.: US 2011/0272763 A1
(43) Pub. Date: Nov. 10, 2011

(54) SEMICONDUCTOR DEVICE AND METHOD FOR FABRICATING THE SAME

(76) Inventors: Yuichiro Sasaki, Nara (JP); Katsumi Okashita, Tokyo (JP); Bunji Mizuno, Nara (JP)

(21) Appl. No.: 13/144,059

(22) PCT Filed: Dec. 17, 2009
(86) PCT No.: PCT/JP2009/006959

§ 371 Date: Jul. 11, 2011

(30) Foreign Application Priority Data
Feb. 12, 2009 (JP) 2009-029459

(51) Int. Cl. H01L 29/772; H01L 21/336

(52) U.S. Cl. 257/347; 438/151; 438/299; 438/299; 257/E29.242; 257/E21.409

(57) ABSTRACT

Extension regions (17) are provided in side portions of a fin-shaped semiconductor region (13) formed on a substrate (11). A gate electrode (15) is formed to extend across the fin-shaped semiconductor region (13) and to be adjacent to the extension regions (17). A resistance region (37) having a resistivity higher than that of the extension regions (17) is formed in an upper portion of the fin-shaped semiconductor region (13) adjacent to the gate electrode (15).

### TECHNICAL FIELD

This disclosure relates to a semiconductor device and a method for fabricating the same and, in particular, to a semiconductor device with a double-gate structure including fin-shaped semiconductor regions on a substrate and a method for fabricating the same.

### BACKGROUND ART

In recent years, demands for miniaturizing semiconductor devices have been increasing along with the increase in the degree of integration, functionality and speed thereof. In view of this, various device structures have been proposed in the art, aiming at the reduction in the area of the substrate taken up by transistors. Among others, attention has been drawn to field effect transistors (FETs) having fin-shaped structures. A field effect transistor having a fin-shaped structure is commonly called a FinFET, and has an active region consisting of thin wall (fin)-like semiconductor regions perpendicular to the principle plane of the substrate. The FinFET can employ a tri-gate structure in which each side surface of the fin-shaped semiconductor region as well as the upper surface of the semiconductor region is used as a channel surface, whereby it is possible to reduce the area on the substrate taken up by the transistor (see, for example, Patent Document 1 and Non-Patent Document 1).

FIGS. 13(a) through 13(e) show a structure of a conventional tri-gate FinFET. FIG. 13(a) is a plan view, FIG. 13(b) is a cross-sectional view taken along line A-A in FIG. 13(a), FIG. 13(c) is a cross-sectional view taken along line B-B in FIG. 13(a), FIG. 13(d) is a cross-sectional view taken along line C-C in FIG. 13(a), and FIG. 13(e) is a cross-sectional view taken along line D-D in FIG. 13(a).

As shown in FIGS. 13(a) through 13(e), a conventional tri-gate FinFET includes a supporting substrate 101 made of silicon, an insulating layer 102 made of silicon oxide formed on the supporting substrate 101, fin-shaped semiconductor regions 103a to 103d formed on the insulating layer 102, a gate electrode 105 formed on the fin-shaped semiconductor regions 103a to 103d with gate insulating films 104a to 104d interposed therebetween, insulating sidewall spacers 106 formed on side surfaces of the gate electrode 105, extension regions 107 formed in opposing regions of the fin-shaped semiconductor regions 103a to 103d that are opposing with the gate electrode 105 interposed therebetween, and source/drain regions 117 formed in opposing regions of the fin-shaped semiconductor regions 103a to 103d that are opposing with the gate electrode 105 and the insulating sidewall spacer 106 interposed therebetween. The fin-shaped semiconductor regions 103a to 103d are placed on the insulating layer 102 so as to be arranged at regular intervals in the gate width direction. The gate electrode 105 is formed so as to extend across the fin-shaped semiconductor regions 103a to 103d in the gate width direction. The extension regions 107 include first impurity regions 107a formed in upper portions of the fin-shaped semiconductor regions 103a to 103d and second impurity regions 107b formed in side portions of the fin-shaped semiconductor regions 103a to 103d. The source/drain regions 117 include third impurity regions 117a formed in upper portions of the fin-shaped semiconductor regions 103a to 103d and fourth impurity regions 117b formed in side portions of the fin-shaped semiconductor regions 103a to 103d. Note that pocket regions are neither described herein nor shown in the drawings.

In this conventional tri-gate FinFET, however, voltages are applied to upper corners of the fin-shaped semiconductor regions 103a to 103d to be channel regions, not only from portions of the gate electrode 105 located on top of the fin-shaped semiconductor regions 103a to 103d but also portions of the gate electrode 105 located on the sides of the fin-shaped semiconductor regions 103a to 103d, as illustrated in FIG. 13(b). Accordingly, these upper corners are likely to be electrically unstable.

To prevent this, a double-gate FinFET in which an upper surface of the fin-shaped semiconductor region is covered with a hard mask so as to use only both side surfaces of the fin-shaped semiconductor regions as channel surfaces is proposed (see, for example, Non-Patent Document 2).

FIG. 14 is a cross-sectional view illustrating a conventional double-gate FinFET. FIG. 14 corresponds to a cross-sectional structure of the conventional tri-gate FinFET illustrated in FIG. 13(b). In FIG. 14, components of the conventional tri-gate FinFET also shown in FIGS. 13(a) through 13(e) are denoted by the same reference numerals, and description of these components is omitted. As illustrated in FIG. 14, in the conventional double-gate FinFET, a hard mask 150 of, for example, a silicon oxide film is interposed between the gate electrode 105 (specifically, the gate insulating films 104a to 104d) and the respective upper surfaces of the fin-shaped semiconductor regions 103a to 103d. In this structure, only the side surfaces of the fin-shaped semiconductor regions 103a to 103d serve as channel surfaces.

The conventional double-gate FinFET has the same planar structure as that of the conventional tri-gate FinFET illustrated in FIG. 13(a). The cross-sectional structures of the conventional double-gate FinFET taken along lines B-B and C-C in FIG. 13(a) are also the same as those of the conventional tri-gate FinFET illustrated in FIGS. 13(c) and 13(d). Although not shown, the cross-sectional structure of the conventional double-gate FinFET taken along line D-D in FIG. 13(a) is different from that of the conventional tri-gate FinFET in FIG. 13(e), in that the hard mask 150 is interposed between the upper surface of the fin-shaped semiconductor region 103b and the gate electrode 105 (specifically, the gate insulating film 104b).

### CITATION LIST

### Patent Document

PATENT DOCUMENT 1: Japanese Laid-Open Patent Publication No.2006-196821

### Non-Patent Document

NON-PATENT DOCUMENT 1: D. Lenoble, et al., Enhanced performance of PMOS MUGFET via integration of conformal plasma-doped source/drain extensions, 2006 Symposium on VLSI Technology Digest of Technical Papers, p. 212

NON-PATENT DOCUMENT 2: Jean-Pierre Colinge, FinFETs and Other Multi-Gate Transistors, Series on Integrated Circuits and Systems, pp. 14-19

### SUMMARY OF THE INVENTION

### Technical Problem

Disadvantageously, the conventional double-gate FinFET cannot exhibit desirable transistor characteristics.

It is, therefore, an object of this disclosure to obtain desirable characteristics in a double-gate semiconductor device including fin-shaped semiconductor regions.

### Solution To the Problem

To achieve the object, inventors of the present invention have studied the reason why desirable transistor characteristics cannot be obtained in a conventional double-gate FinFET, leading to the following findings.

In the case of performing extension implantation for forming a conventional double-gate FinFET by employing an ion implantation method or a plasma doping method, the gate electrode 105 serves as a mask in the cross-sectional view of FIG. 14, and thus, no impurities are implanted in the fin-shaped semiconductor regions 103a to 103d. Specifically, during the extension implantation process, no impurities are implanted in side and upper portions of the fin-shaped semiconductor regions 103a to 103d covered with the gate electrode 105.

On the other hand, in the cross-sectional view (where the insulating sidewall spacer 106 in FIG. 13(c) and the source/drain regions 117 in FIG. 13(d) are not formed in the extension implantation process) illustrated in FIGS. 13(c) and 13(d), an impurity is implanted in the fin-shaped semiconductor regions 103a to 103d.

FIG. 15(a) is a cross-sectional view showing extension implantation with an ion implantation method. FIG. 15(b) is a cross-sectional view showing extension implantation with a plasma doping method. In FIGS. 15(a) and 15(b), components of the conventional FinFET also illustrated in FIGS. 13(a) through 13(e) are denoted by the same reference numerals, and description of these components is omitted.

In the case of employing an ion implantation method for extension implantation as illustrated in FIG. 15(a), ions 108a and 108b are implanted in the fin-shaped semiconductor regions 103a to 103d at implantation angles inclined in different directions from the vertical direction in order to introduce impurities not only into upper surfaces but also into side surfaces of the fin-shaped semiconductor regions 103a to 103d, thereby forming extension regions 107. In this case, the upper portion of each of the fin-shaped semiconductor regions 103a to 103d is doped with both of the ions 108a and 108b, thereby forming a first impurity region 107a. On the other hand, the side portions of each of the fin-shaped semiconductor regions 103a to 103d are doped with only the ions 108a or 108b, thereby forming second impurity regions 107b. Thus, if the dose of the ions 108a and the dose of the ions 108b are equal to each other, the implantation dose of the first impurity region 107a is twice as large as that of the second impurity regions 107b. As a result, the first impurity region 107a has a resistivity lower than that of the second impurity regions 107b by about 50%, for example.

In the case of employing a plasma doping method for extension implantation as illustrated in FIG. 15(b), a first impurity region 107a is formed in an upper portion of each of the fin-shaped semiconductor regions 103a to 103d. The implantation dose of the first impurity region 107a is determined by the balance among implanted ions 109a, an adsorbed species (a neutral species such as gas molecules or radicals) 109b, and an impurity 109c that is desorbed from the fin-shaped semiconductor regions 103a to 103d by sputtering. However, the implantation dose of the side portions of each of the fin-shaped semiconductor regions 103a to 103d is less influenced by the implanted ions 109a and the impurity 109c desorbed by sputtering. Thus, second impurity regions 107b whose implantation dose is mainly determined by the adsorbed species 109b are formed in side portions of each of the fin-shaped semiconductor regions 103a to 103d. As a result, the implantation dose of the first impurity region 107a is larger than that of the second impurity regions 107b by about 25%, for example, whereby the resistivity of the first impurity region 107a is lower than that of the second impurity regions 107b by about 25%, for example.

As described above, with the conventional method for forming extension regions of a double-gate FinFET, the resistivity of the first impurity region 107a formed in the upper portion of each of the fin-shaped semiconductor regions 103a to 103d is lower than that of the second impurity regions 107b in the side portions of each of the fin-shaped semiconductor regions 103a to 103d. When a double-gate FinFET having such an extension structure is operated, current flowing in the extension regions 107 is concentrated in the first impurity region 107a having a lower resistivity than the second impurity regions 107b (see FIG. 13(c)). On the other hand, channel is formed only in side portions of the fin-shaped semiconductor regions 103a to 103d covered with the gate electrode 105, and upper portions of the fin-shaped semiconductor regions 103a to 103d covered with the hard mask 150 do not function as channel (see FIG. 14). This is a feature of double-gate FinFETs, and is achieved by covering upper portions of the fin-shaped semiconductor regions 103a to 103d with the hard mask 150 so as to prevent the upper portions of the fin-shaped semiconductor regions 103a to 103d from being influenced by an electric field from the gate electrode 105 for the purpose of accurate transistor control. Accordingly, although current flowing in the extension regions 107 is concentrated in the first impurity region 107a in the upper portion of each of the fin-shaped semiconductor regions 103a to 103d, channel is present only in the side portions of each of the fin-shaped semiconductor regions 103a to 103d. Consequently, a larger amount of current flowing in channel is present at a relatively shallow level in the side portions of the fin-shaped semiconductor regions 103a to 103d. In other words, in a channel region covered with the gate electrode 105, the amount of current flowing at a relatively deep level in the side portions of the fin-shaped semiconductor regions 103a to 103d is smaller than that of current flowing at a relatively shallow level in the side portions of the fin-shaped semiconductor regions 103a to 103d. Specifically, current flowing in an ON state is not uniform in the side portions of the fin-shaped semiconductor regions 103a to 103d to be channel, resulting in undesirable transistor characteristics.

Inventors of the present invention found that the use of a plasma doping method in extension implantation for a conventional double-gate FinFET has a drawback as follows: As shown in FIG. 16(a), when a plasma doping method (in which plasma-generating gas is gas mixture of B₂H₆ and He) is applied to a flat semiconductor region 151, the amount of chipping of silicon of the semiconductor region 151 is smaller than or equal to 1 (one) nm/min. On the other hand, as shown in FIG. 16(b), when an impurity region is formed in a fin-shaped semiconductor region by using the plasma doping method described above, the amount of chipping of an upper corner of a fin-shaped semiconductor region 152 on the flat semiconductor region 151 is larger than 10 nm/min.

FIG. 17 is a perspective view illustrating a device in which a gate electrode is formed on a fin-shaped semiconductor region having such a problem as described above with a gate insulating film interposed therebetween. As illustrated in FIG. 17, a gate electrode 163 is formed to extend across a fin-shaped semiconductor region 161 having an impurity region 161a in an upper portion thereof and impurity regions 161b in side portions thereof. Specifically, a hard mask 164 and a gate insulating film 162 are stacked in this order between the upper surface of the fin-shaped semiconductor region 161 and the gate electrode 163. The gate insulating film 162 is also sandwiched between the side surface of the fin-shaped semiconductor region 161 and the gate electrode 163. In FIG. 17, a, b, c, and d denote corners at the source side along the inner wall of a pommel horse shape constituted by the gate insulating film 162 and the hard mask 164, and a″, b″, c″, and d″ are corners obtained by translating the corners a, b, c, and d to the source-side end facet of the fin-shaped semiconductor region 161.

In general, a sidewall spacer (not shown in FIG. 17) is formed on an extension region to protect the extension region after extension implantation. The source-side end facet mentioned above is a portion of the semiconductor region which is covered with the sidewall spacer, and is located farthest away from channel. The amount G of chipping of an upper corner of the fm-shaped semiconductor region 161 is the distance from the upper corner to b″ or c″. Assuming that the radius of curvature of the upper corner is r, G=(2^{0.5}−1)r holds (where the radius of curvature of the upper corner before doping is 0 (zero), i.e., the corner forms a right angle).

If the amount G of chipping of the upper corner of the fin-shaped semiconductor region 161 increases, there will be an unintended gap between the impurity region 161a or 161b to be, for example, the extension region and the inner-wall corner b or c of a pommel horse shape constituted by the gate insulating film 162 and the hard mask 164. When a double-gate FinFET having such an extension structure is operated, current is less likely to flow in an upper corner (i.e., the uppermost portion of a side portion of the fin-shaped semiconductor region 161 to be channel) of the fin-shaped semiconductor region 161 to be the extension region. As a result, desirable transistor characteristics cannot be obtained.

Based on the foregoing findings, the inventors have invented that extension regions are formed only in side portions of a fin-shaped semiconductor region, whereas a resistance region having a higher resistivity than the extension regions is formed in an upper portion of the fin-shaped semiconductor region.

According to this disclosure, current flowing in the extension regions is present only in the side portions of the fin-shaped semiconductor region. In other words, this current does not flow in the upper portion of the fin-shaped semiconductor region. Accordingly, even in a fin-shaped semiconductor region in a channel region covered with a gate electrode, current can uniformly flow in side portions of the region. Specifically, current flowing in an ON state is uniform in side portions of the fin-shaped semiconductor region to be channel. As a result, desirable transistor characteristics can be obtained in a double-gate FinFET.

Unlike a conventional double-gate FinFET, this advantage can be obtained without employing a structure in which a hard mask is provided between the upper surface of a fin-shaped semiconductor region and a gate electrode. Accordingly, it is possible to employ a structure including no hard mask, thus achieving a remarkable advantage of highly-advanced miniaturization and a remarkable advantage of a considerable increase in throughput due to simplified processes.

According to this disclosure, a resistance region is provided in an upper portion of a fin-shaped semiconductor region. This structure stabilizes electrical characteristics at an upper corner of the fin-shaped semiconductor region. Accordingly, even when the amount of chipping at the upper corner of the fin-shaped semiconductor region increases, i.e., an unwanted gap occurs between an inner-wall corner of a gate insulating film having a pommel horse shape and an upper corner of the fin-shaped semiconductor region at the outside of the gate insulating film (i.e., at the outside of the gate electrode), degradation of transistor characteristics can be prevented.

Assuming that a target has a resistivity (specific resistance) of Rr, a sheet resistance of Rs, a thickness (junction depth) oft, and a spreading resistance of Rw, Rs is proportional to Rr/t. Further, as expressed in the relational expression Rw=CF×k×Rr/(2×3.14×r), which is widely known in the spreading resistance measurement, the resistivity (specific resistance) Rr and the spreading resistance Rw are in principal in a one-to-one relationship to lead to establishment of a proportional relationship between Rs and Rw/t. In the aforementioned relational expression, CF is a correction term taking the volume effect of the spreading resistance Rw taken into consideration (CF=1 where the correction term is absent), k is a correction term taking the polarity dependence of the Schottky barrier between a probe and a sample into consideration (k=1 where the sample is p-type silicon and k=1 to 3 where the sample is n-type silicon, for example), and r is a radius of curvature of the tip end of the probe. The following description mainly employs “resistivity (specific resistance).” However, “resistivity (specific resistance)” may be rendered as “sheet resistance” or “spreading resistance” for the level of the resistance.

Specifically, an example semiconductor device includes: a fin-shaped semiconductor region formed on a substrate and including an extension region in each side portion of the fin-shaped semiconductor region; a gate electrode formed to extend across the fin-shaped semiconductor region and to be adjacent to the extension regions; and a resistance region formed in an upper portion of the fin-shaped semiconductor region adjacent to the gate electrode, the resistance region having a resistivity higher than that of the extension regions.

The semiconductor device may further include a gate insulating film, the gate insulating film being formed on the fin-shaped semiconductor region so as to be disposed between the gate electrode and the fin-shaped semiconductor region.

The semiconductor device may further include insulating sidewall spacers formed so as to cover a side surface of the gate electrode, the resistance region being disposed beneath the insulating sidewall spacers.

In the semiconductor device, the resistance region may be formed in substantially the upper portion of the fin-shaped semiconductor region except a portion of the fin-shaped semiconductor region located beneath the gate electrode.

In the semiconductor device, the resistance region may be formed in the upper portion of the fin-shaped semiconductor region that extends laterally from the gate electrode.

In the semiconductor device, the resistance region may be formed in substantially the upper portion of the fin-shaped semiconductor region that extends laterally from the gate electrode.

In the semiconductor device, a channel in which current flows during an ON state may be formed in the side portions of the fin-shaped semiconductor region covered with the gate electrode. In this case, the resistance region may be configured to limit a current flow in the upper portion of the fin-shaped semiconductor region during the ON state. In addition, in this case, a larger amount of current may flow in the channel than that in the resistance region during the ON state.

In the semiconductor device, the upper portion of the fin-shaped semiconductor region may not function as a channel during operation.

In the semiconductor device, current flow occurring during an ON state may be substantially uniform in the side portions of the fm-shaped semiconductor region covered with the gate electrode.

In this semiconductor device, the presence of an amorphous region in the resistance region ensures that a resistance region having a resistivity higher than that of the extension region in each of the side portions of the fin-shaped semiconductor region is formed in an upper portion of the fin-shaped semiconductor region. In this case, if the amorphous region contains a crystallization inhibitor such as germanium, argon, fluorine, or nitrogen, a resistance region including an amorphous region is formed as intended. As the crystallization inhibitor, an impurity, such as arsenic, of a conductivity type opposite to the conductivity type of the extension region may be introduced.

In the semiconductor device, introduction of an impurity of a conductivity type opposite to that of the extension region in the resistance region ensures that a resistance region having a resistivity higher than that of the extension region in each of the side portions of the fin-shaped semiconductor region is formed in an upper portion of the fin-shaped semiconductor region.

In the semiconductor device, the fin-shaped semiconductor region may be provided on an insulating layer formed on the substrate.

In the semiconductor device, an insulating sidewall spacer may be formed to cover the extension region, the resistance region, and each side surface of the gate electrode, and source/drain regions may be formed in at least side portions of the fin-shaped semiconductor each located outside the insulating sidewall spacer away from the gate electrode.

In the semiconductor device, if the fin-shaped semiconductor region has a side surface whose height is greater than a width in a gate width direction of an upper surface of the fin-shaped semiconductor region, the advantages of the present invention described above can be significantly exhibited, as compared to the conventional techniques.

A first example method for fabricating a semiconductor device includes the steps of: (a) forming a fin-shaped semiconductor region on a substrate; (b) forming a gate electrode across the fin-shaped semiconductor region; (c) introducing an impurity into an upper portion of the fin-shaped semiconductor region and side portions of the fin-shaped semiconductor region so as to form a first impurity region in the upper portion of the fin-shaped semiconductor region and a second impurity region in each of the side portions of the fin-shaped semiconductor region; and (d) electrically activating the impurity introduced into the first impurity region and the second impurity region, wherein a process condition for at least one of steps (c) and (d) is selected such that the first impurity region is in at least a partially amorphous state.

This first example method ensures fabrication of the semiconductor device described above, thus obtaining the aforementioned advantages. In particular, since effective channel is formed only in side portions of a fin-shaped semiconductor region in a double-gate FinFET, it is very important, as in this disclosure, to minimize the resistivity of an impurity region formed as an extension region in a side portion of the fin-shaped semiconductor region to a value lower than the resistivity of an impurity region formed in an upper portion of the fin-shaped semiconductor region.

In the first example method, the gate electrode may be utilized as a mask when introducing the impurity.

In the first example method, the impurity may be electrically activated by utilizing a heat treatment.

In the first example method, a resistivity of the first impurity region in the partially amorphous state may be higher than that of the second impurity region.

Specifically, in the first example method, in step (c), a plasma doping method may be employed, and a bias voltage during plasma doping may be adjusted such that a first amorphous region formed in an upper portion of the fin-shaped semiconductor region has a thickness larger than that of a second amorphous region formed in each side portion of the fin-shaped semiconductor region. Note that while the lower limit of the pressure during plasma doping can be set to be low within such a range that does not present problems with respect to the throughput, the limitations of the apparatus, etc., the lower limit is about 0.1 Pa in view of the performance of state-of-the-art plasma apparatus, etc., and is about 0.01 Pa in view of the performance of plasma apparatus to be used in the future.

In this case, in step (d), a temperature of the heat treatment may be selected such that crystal recovery occurs in the second amorphous region, and that the first amorphous region at least partially remains in the amorphous state. In spike RTA (rapid thermal annealing) or millisecond annealing as a specific heat treatment method, heat treatment time is substantially fixed, and thus the thermal budget is substantially based on the setting of the heat treatment temperature.

The first example method may further include the step of introducing a crystallization inhibitor, such as germanium, argon, fluorine, and nitrogen, into an upper portion of the fin-shaped semiconductor region with the gate electrode used as a mask, between steps (b) and (c) or between steps (c) and (d). Then, the first impurity region in the upper portion of the fin-shaped semiconductor region is at least partially in an amorphous state as intended. As the crystallization inhibitor, an impurity, such as arsenic, of a conductivity type opposite to the conductivity type of the extension region may be introduced.

A second example method for fabricating a semiconductor device includes the steps of: (a) forming a fin-shaped semiconductor region on a substrate; (b) forming a gate electrode across the fin-shaped semiconductor region; (c) introducing an impurity of a first conductivity type into an upper portion of the fin-shaped semiconductor region and side portions of the fin-shaped semiconductor region so as to form a first impurity region in the upper portion of the fin-shaped semiconductor region and a second impurity region in each of the side portions of the fin-shaped semiconductor region; (d) electrically activating the impurity of the first conductivity type introduced into the first impurity region and the second impurity region; and (e) introducing an impurity of a second conductivity type opposite to the first conductivity type into an upper portion of the fin-shaped semiconductor region, after step (b).

This second example method ensures fabrication of the semiconductor device described above, thus obtaining the aforementioned advantages. In particular, since effective channel is formed only in side portions of a fin-shaped semiconductor region in a double-gate FinFET, it is very important, as in this disclosure, to minimize the resistivity of an impurity region formed as an extension region in a side portion of the fin-shaped semiconductor region to a value lower than the resistivity of an impurity region formed in an upper portion of the fin-shaped semiconductor region. In the second example method, the step of introducing an impurity of the second conductivity type in the upper portion of the fin-shaped semiconductor region may be performed after step (d) of electrically activating, with heat treatment, the impurity of the first conductivity type.

In the second example method, the gate electrode may be utilized as a mask when introducing the impurity of a first conductivity type and when introducing the impurity of a second conductivity type.

In the second example method, the impurity of the first conductivity type may be electrically activated by utilizing a heat treatment.

The first or second example method may further include the step of foil ling an insulating layer on the substrate. In this case, the fin-shaped semiconductor region may be formed on the insulating layer.

In the first or second example method, the fin-shaped semiconductor region may have a side surface perpendicular to an upper surface of the fin-shaped semiconductor region.

A third example method for fabricating a semiconductor device includes the steps of: forming a fin-shaped semiconductor region on a substrate; forming a gate electrode which extends across the fin-shaped semiconductor region; forming an extension region in each side portion of the fin-shaped semiconductor region adjacent to the gate electrode, and forming a resistance region in an upper portion of the fin-shaped semiconductor region adjacent to the gate electrode, the resistance region having a resistivity higher than that of the extension region.

The third example method for fabricating a semiconductor device may further include the step of forming a gate insulating film on the fin-shaped semiconductor region such that the gate insulating film is disposed between the gate electrode and the fin-shaped semiconductor region.

The third example method for fabricating a semiconductor device may further include the step of forming insulating sidewall spacers so as to cover a side surface of the gate electrode, the resistance region being disposed beneath the insulating sidewall spacers.

In the third example method for fabricating a semiconductor device, the resistance region may be formed in substantially the upper portion of the fin-shaped semiconductor region except a portion of the fin-shaped semiconductor region located beneath the gate electrode.

In the third example method for fabricating a semiconductor device, the step of forming a resistance region may include forming the resistance region so as to be disposed in the upper portion of the fin-shaped semiconductor region that extends laterally from the gate electrode.

In the third example method for fabricating a semiconductor device, the step of forming a resistance region may include forming the resistance region so as to be disposed in substantially the upper portion of the fin-shaped semiconductor region that extends laterally from the gate electrode.

In the third example method for fabricating a semiconductor device, the resistance region may include an amorphous region. In this case, the amorphous region may contain a crystallization inhibitor such as germanium, argon, fluorine, and nitrogen.

### Advantages of the Invention

According to this disclosure, a semiconductor device in which the resistivity of a side portion to be an extension region of a fin-shaped semiconductor region is lower than that of an upper portion of the fin-shaped semiconductor region, i.e., a semiconductor device including a low-resistance extension region in a side portion of a fin-shaped semiconductor region, can be implemented. Accordingly, degradation of characteristics in a three-dimensional device such as a double-gate FinFET can be prevented.

### BRIEF DESCRIPTION OF THE DRAWINGS

FIGS. 1(a) through 1(e) are views illustrating a semiconductor device according to a first example embodiment of the present invention, specifically a structure of a semiconductor device including a FinFET. FIG. 1(a) is a plan view, FIG. 1(b) is a cross-sectional view taken along line A-A in FIG. 1(a), FIG. 1(c) is a cross-sectional view taken along line B-B in FIG. 1(a), FIG. 1(d) is a cross-sectional view taken along line C-C in FIG. 1(a), and FIG. 1(e) is a cross-sectional view taken along line D-D in FIG. 1(a).

FIGS. 2(a) through 2(d) are cross-sectional views showing step by step the method for fabricating a semiconductor device of the first example embodiment.

FIGS. 3(a) through 3(c) respectively illustrate cross-sectional structures of extension regions before extension implantation, immediately after extension implantation, and after heat treatment for impurity activation (i.e., in the state of device completion) in the method for fabricating a semiconductor device according to the first example embodiment.

FIG. 4 schematically shows current flowing in an ON state of gate with side surfaces of a fin-shaped semiconductor region in the semiconductor device of the first example embodiment developed on the same plane (an imaginary plane) as the upper surface of the fin-shaped semiconductor region.

FIG. 5 is a TEM photograph immediately after implantation of an impurity in a fin-shaped semiconductor region by extension implantation according to the fabrication method of the first example embodiment.

FIG. 6(a) is a TEM photograph immediately after plasma doping on a flat surface portion of a semiconductor substrate corresponding to an upper portion of a fin-shaped semiconductor region. FIG. 6(b) is a TEM photograph after heat treatment performed at 925 degrees centigrade with spike RTA after the plasma doping. FIG. 6(c) is a TEM photograph after heat treatment performed at 1000 degrees centigrade with spike RTA after the plasma doping.

FIG. 7 is shows a relationship between a bias voltage and the thickness of an amorphous region in a case where plasma doping using gas mixture of B₂H₆ and He is performed for 60 seconds.

FIG. 8 shows a relationship between a spike RTA temperature and the thickness of amorphous silicon which has recovered to crystal silicon.

FIG. 9 is a perspective view schematically illustrating an example of a specific structure of a semiconductor device obtained by the fabrication method of the first example embodiment.

FIG. 10 is a perspective view schematically illustrating another example of the specific structure of the semiconductor device obtained by the fabrication method of the first example embodiment.

FIGS. 11(a) and 11(b) are cross-sectional views showing step by step a method for fabricating a semiconductor device according to a second example embodiment of the present invention.

FIGS. 12(a) and 12(b) are cross-sectional views showing step by step a method for fabricating a semiconductor device according to a third example embodiment of the present invention.

FIGS. 13(a) through 13(e) show a structure of a conventional tri-gate FinFET. FIG. 13(a) is a plan view, FIG. 13(b) is a cross-sectional view taken along line A-A in FIG. 13(a), FIG. 13(c) is a cross-sectional view taken along line B-B in FIG. 13(a), FIG. 13(d) is a cross-sectional view taken along line C-C in FIG. 13(a), and FIG. 13(e) is a cross-sectional view taken along line D-D in FIG. 13(a).

FIG. 14 is a cross-sectional view illustrating a conventional double-gate FinFET.

FIG. 15(a) is a cross-sectional view showing extension implantation with an ion implantation method. FIG. 15(b) is a cross-sectional view showing extension implantation with a plasma doping method.

FIGS. 16(a) and 16(b) are views for explaining a problem in applying a plasma doping method to extension implantation for a conventional double-gate FinFET.

FIG. 17 is a perspective view illustrating a device in which a gate electrode is formed on a fin-shaped semiconductor region having a problem as illustrated in FIG. 16(b) with a gate insulating film interposed between the gate electrode and the fin-shaped semiconductor region.

### DESCRIPTION OF EMBODIMENTS

### First Example Embodiment

Hereinafter, a semiconductor device and a method for fabricating a semiconductor device according to a first example embodiment of the present invention will be described with reference to the drawings.

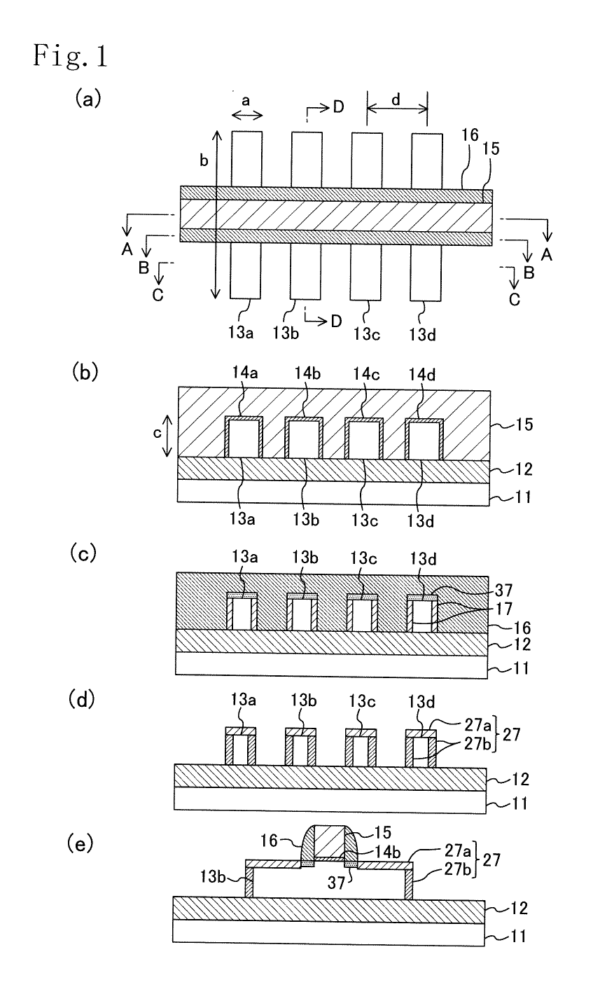

FIGS. 1(a) through 1(e) are views illustrating a semiconductor device of this embodiment, specifically a structure of a semiconductor device including FinFETs. FIG. 1(a) is a plan view, FIG. 1(b) is a cross-sectional view taken along line A-A in FIG. 1(a), FIG. 1(c) is a cross-sectional view taken along line B-B in FIG. 1(a), FIG. 1(d) is a cross-sectional view taken along line C-C in FIG. 1(a), and FIG. 1(e) is a cross-sectional view taken along line D-D in FIG. 1(a).

As shown in FIGS. 1(a) through 1(e), the FinFETs of the this embodiment include a supporting substrate 11 made of silicon, for example, an insulating layer 12 made of silicon oxide, for example, formed on the supporting substrate 11, fin-shaped semiconductor regions 13a to 13d formed on the insulating layer 12, a gate electrode 15 formed on the fin-shaped semiconductor regions 13a to 13d with gate insulating films 14a to 14d made of a silicon oxynitride film, for example, interposed therebetween, insulating sidewall spacers 16 formed on the side surfaces of the gate electrode 15, extension regions 17 formed in opposing regions of the fin-shaped semiconductor regions 13a to 13d that are opposing each other with the gate electrode 15 interposed therebetween, and source/drain regions 27 formed in opposing regions of the fin-shaped semiconductor regions 13a to 13d that are opposing each other with the gate electrode 15 and the insulating sidewall spacers 16 interposed therebetween. The gate electrode 15 is formed to extend across the fin-shaped semiconductor regions 13a to 13d in the gate width direction. Note that pocket regions are neither described herein nor shown in the figures.

The fin-shaped semiconductor regions 13a to 13d each have a width ‘a’ in the gate width direction of about 22 nm, for example, a width ‘b’ in the gate length direction of about 350 nm, for example, and a height (thickness) ‘c’ of about 65 nm, for example, and are arranged with a pitch ‘d’ (about 44 nm, for example) in the gate width direction on the insulating layer 12. The upper surface and the side surface of each of the fin-shaped semiconductor regions 13a to 13d may or may not be perpendicular to each other.

A feature of this embodiment is now described. The extension regions 17 are formed only in side portions of the fin-shaped semiconductor regions 13a to 13d covered with the insulating sidewall spacers 16 (i.e., regions of the fin-shaped semiconductor regions 13a to 13d adjacent to the gate electrode 15), whereas a resistance region 37 having a higher resistivity than the extension regions 17 is formed in upper portions of the fin-shaped semiconductor regions 13a to 13d covered with the insulating sidewall spacers 16. In this embodiment, the resistance region 37 is an impurity region that is at least partially in an amorphous state. That is, the semiconductor device of this embodiment is a semiconductor device including double-gate FinFETs.

In this embodiment, the source/drain regions 27 include impurity regions 27a and 28b respectively defined in upper and side portions of the fin-shaped semiconductor regions 13a to 13d located at the sides of the insulating sidewall spacers 16 opposite the gate electrode 15. Alternatively, in the same manner as for the extension regions 17, a resistance region may be provided in upper portions of the fin-shaped semiconductor regions 13a to 13d so that the source/drain regions 27 are formed only in side portions of the fin-shaped semiconductor regions 13a to 13d.

In the above-described structure of this embodiment, current flowing in the extension regions 17 is present only in side portions of the fin-shaped semiconductor regions 13a to 13d, i.e., is absent in upper portions of the fin-shaped semiconductor regions 13a to 13d. Accordingly, current is allowed to uniformly flow in side portions of the fin-shaped semiconductor regions 13a to 13d in a channel region covered with the gate electrode 15. That is, current flowing in an ON state is uniformly distributed in side portions of the fin-shaped semiconductor regions 13a to 13d to be channel. Consequently, desired transistor characteristics can be obtained in the double-gate FinFETs. In particular, as the height of the side surfaces of the fin-shaped semiconductor regions 13a to 13d increases as compared to the width in the gate width direction of the upper surfaces of the fin-shaped semiconductor regions 13a to 13d, the aforementioned advantages of this embodiment are more greatly exhibited than those of conventional techniques.

Unlike conventional double-gate FinFETs, the aforementioned advantages of this embodiment are obtained without employing a structure in which a hard mask is provided between the upper surface of a fin-shaped semiconductor region and a gate electrode. Accordingly, a structure without a hard mask can be employed, leading to highly-advanced miniaturization and to a considerable increase in throughput due to simplified processes.

In addition, in this embodiment, the presence of the resistance region 37 in upper portions of the fin-shaped semiconductor regions 13a to 13d stabilizes electrical characteristics of the fin-shaped semiconductor regions 13a to 13d at upper corners thereof. Accordingly, even when the amount of chipping of the upper corners of the fin-shaped semiconductor regions 13a to 13d increases, i.e., unwanted gaps occur between inner-wall corners of the gate insulating films 14a to 14d having pommel horse shapes and upper corners of the fin-shaped semiconductor regions 13a to 13d at the outside of the gate insulating films 14a to 14d (i.e., at the outside of the gate electrode 15), degradation of transistor characteristics can be prevented.

A method for fabricating a semiconductor device according to the first example embodiment is now described with reference to the drawings.

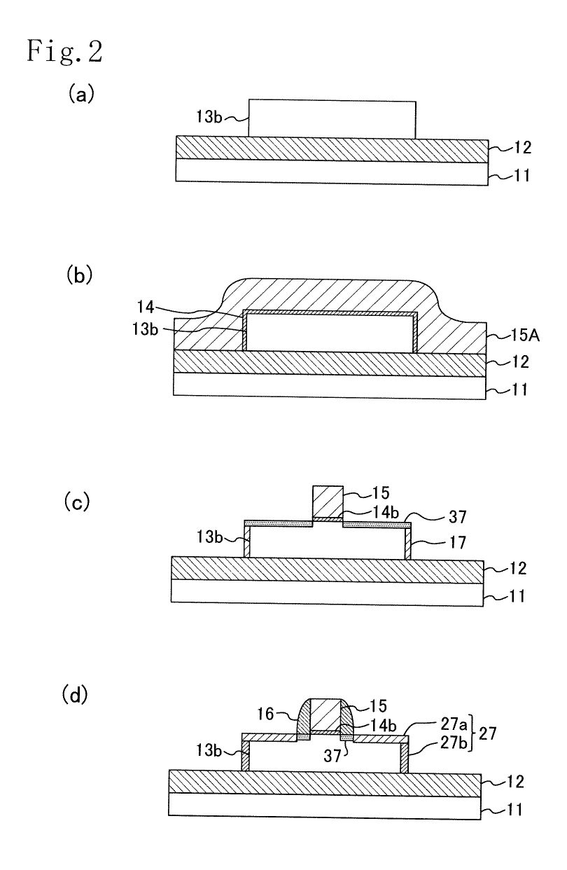

FIGS. 2(a) through 2(d) are cross-sectional views showing step by step the method for fabricating a semiconductor device of the first example embodiment. Note that FIGS. 2(a) through 2(d) correspond to the cross-sectional structure taken along line D-D in FIG. 1(a).

First, as shown in FIG. 2(a), an SOI (semiconductor on insulator) substrate in which a semiconductor layer having a thickness of 65 nm and made of silicon, for example, is provided over a supporting substrate 11 having a thickness of 775 micro meters and made of silicon, for example, with an insulating layer 12 having a thickness of 150 nm and made of silicon oxide, for example, interposed therebetween is prepared. Then, the semiconductor layer is patterned to form an n-type fin-shaped semiconductor region 13b to be an active region. The fin-shaped semiconductor region 13b has a width ‘a’ in the gate width direction of about 22 nm, for example, a width ‘b’ in the gate length direction of about 350 nm, for example, and a height (thickness) ‘c’ of about 65 nm, for example, and is arranged, with other adjacent fin-shaped semiconductor regions, with a pitch ‘d’ (about 44 nm, for example). In this embodiment, the patterning is performed such that the side surface of the fin-shaped semiconductor region 13b is perpendicular to the upper surface of the fin-shaped semiconductor region 13b.

Next, as shown in FIG. 2(b), a gate insulating film 14 having a thickness of 2 nm and made of hafnium oxide, for example, is formed to cover the upper and side surfaces of the fin-shaped semiconductor region 13b. Thereafter, a polysilicon film 15A having a thickness of 20 nm, for example, is formed over the entire surface of the supporting substrate 11.

Then, as shown in FIG. 2(c), a resist pattern (not shown) is formed over the polysilicon film 15A to cover a gate electrode region with, for example, a double-patterning technique. Using this resist pattern as a mask, the polysilicon film 15A is etched, thereby forming a gate electrode 15 on the fin-shaped semiconductor region 13b. Thereafter, the resist pattern is removed. In this process, the gate insulating film 14 is also etched, thereby leaving a gate insulating film 14b under the gate electrode 15. The gate electrode 15 has a length in the gate length direction of about 38 nm, for example, on the upper surface of the fin-shaped semiconductor region 13b. The gate electrode 15 is formed to extend across the fin-shaped semiconductor region 13b in the gate width direction (see FIG. 1(b)).

Then, using the gate electrode 15 as a mask, upper and side portions of the fin-shaped semiconductor region 13b are doped with a p-type impurity (e.g., boron) with a plasma doping method. During this doping, a plasma doping condition, e.g., a bias voltage, is adjusted such that an amorphous region formed in the upper portion of the fin-shaped semiconductor region 13b is thicker than amorphous regions formed in the side portions of the fin-shaped semiconductor region 13b. In this manner, p-type impurity regions to be extension regions 17 are formed in the side portions of the fin-shaped semiconductor region 13b, whereas a resistance region 37 having a higher resistivity than the extension regions 17 is formed in the upper portion of the fin-shaped semiconductor region 13b.

In this embodiment, the pressure during plasma doping for forming the extension regions 17 is set to be lower than or equal to 0.6 Pa. Thus, the implantation dose of the side portions of the fin-shaped semiconductor region 13b is larger than or equal to 80% of that of the upper portion of the fin-shaped semiconductor region 13b. Specifically, the plasma doping condition is such that the material gas is B₂H₆ (diborane) diluted with He (helium), the B₂H₆ concentration in the material gas is 0.5% by mass, the total flow rate of the material gas is 100 cm³/min (standard condition), the chamber pressure is 0.35 Pa, the source power (plasma-generating high-frequency power) is 500 W, the bias voltage (Vpp) is 430 V, and the plasma doping time is 60 seconds.

Using the gate electrode 15 as a mask, the fin-shaped semiconductor region 13b is then ion-implanted with an impurity to form an n-type pocket region (not shown).

Thereafter, as shown in FIG. 2(d), an insulating film having a thickness of 25 nm, for example, is formed over the entire surface of the supporting substrate 11, and then the insulating film is etched back by anisotropic dry etching, thereby forming insulating sidewall spacers 16 on the side surfaces of the gate electrode 15.

Using the gate electrode 15 and the insulating sidewall spacers 16 as a mask, upper and side portions of the fin-shaped semiconductor region 13b are subsequently doped with a p-type impurity (e.g., boron) with a plasma doping method. Accordingly, as shown in FIG. 2(d), p-type impurity regions 27a to be part of the source/drain regions 27 are formed in the upper portion of the fin-shaped semiconductor region 13b at the outside of the insulating sidewall spacers 16, whereas p-type impurity regions 27b to be part of the source/drain regions 27 are formed in the side portions of the fin-shaped semiconductor region 13b at the outside of the insulating sidewall spacers 16.

In this embodiment, the pressure during plasma doping for forming the source/drain regions 27 is set to be lower than or equal to 0.6 Pa (where doping time is 60 seconds, for example). Thus, the implantation dose of the side portions of the fin-shaped semiconductor region 13b is larger than or equal to 80% of that of the upper portion of the fin-shaped semiconductor region 13b.

Then, to electrically activate the impurities introduced into the extension regions 17 and the source/drain regions 27 with heat treatment, a spike RTA, for example, is performed at a temperature of about 1000 degrees centigrade. In this heat treatment, heat treatment temperature and heat treatment time are adjusted such that crystal recovery occurs in the amorphous region in the side portions (i.e., the extension regions 17) of the fin-shaped semiconductor region 13b and that the amorphous region in the upper portion (i.e., the resistance region 37) of the fin-shaped semiconductor region 13b at least partially remains in the amorphous state. In this manner, in the complete semiconductor device, the resistivity of the extension regions 17 is lower than that of the resistance region 37, thus obtaining desired transistor characteristics. In the case of employing spike RTA or millisecond annealing as a specific heat treatment method, heat treatment time is substantially fixed, and thus the thermal budget is substantially based on the setting of the heat treatment temperature.

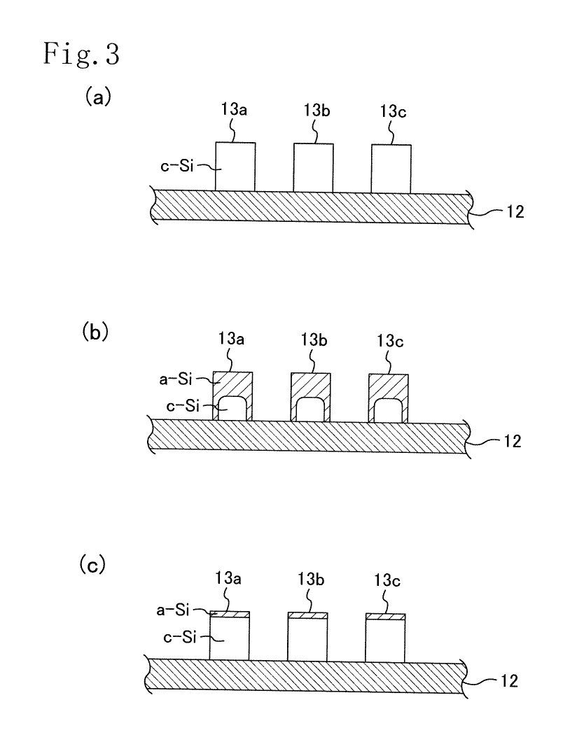

That is, features of the fabrication method of this embodiment are:
(1) The implantation dose of the extension regions 17 formed in the side portions of the fin-shaped semiconductor region 13b is larger than or equal to 80% of that of the resistance region 37 formed in the upper portion of the fin-shaped semiconductor region 13b;
(2) Immediately after extension implantation, the amorphous region in the resistance region 37 formed in the upper portion of the fin-shaped semiconductor region 13b is thicker than the amorphous regions in the extension regions 17 formed in the side portions of the fin-shaped semiconductor region 13b (see FIGS. 3(b)); and
(3) After heat treatment for impurity activation, the amorphous regions in the extension regions 17 formed in the side portion of the fin-shaped semiconductor region 13b is recovered to crystal, whereas part (a surface portion) of the amorphous region in the resistance region 37 formed in the upper portion of the fin-shaped semiconductor region 13b remains in an amorphous state (see FIG. 3(c)).
   where FIGS. 3(a) through 3(c) respectively illustrate cross-sectional structures of the extension regions before extension implantation, immediately after extension implantation, and after heat treatment for impurity activation (i.e., in the state of device completion). In FIGS. 3(a) through 3(c), a-Si is an amorphous region, and c-Si is a crystal region. In FIGS. 3(a) through 3(c), components of the semiconductor device also shown in FIGS. 1(a) through 1(e) are denoted by the same reference numerals.

With the foregoing features of this embodiment, the resistivity of the extension regions in the side portions of the fin-shaped semiconductor region is lower than that in the upper portion of the fin-shaped semiconductor region. Accordingly, even in a double-gate FinFET in which only side portions of a fin-shaped semiconductor region are used as channel, desired transistor characteristics can be obtained. Specifically, when a double-gate FinFET having an extension structure as in this embodiment is operated, current flowing in an ON state of gate is mainly present in the extension regions 17 formed in the side portions of the fin-shaped semiconductor region 13 and having a lower resistivity than that of the resistance region 37 formed in the upper portion of the fin-shaped semiconductor region 13. Accordingly, current from the extension regions 17 in the side portions of the fin-shaped semiconductor region 13 also flows in side portions of the fin-shaped semiconductor region 13 in channel, thus allowing a smooth flow of the current. Consequently, in the side portions of the fin-shaped semiconductor region 13, the amount of current flowing in channel at a relatively shallow level in the side portions is almost equal to that of current flowing in channel at a relatively deep level in the side portions. As a result, desired transistor characteristics can be obtained.

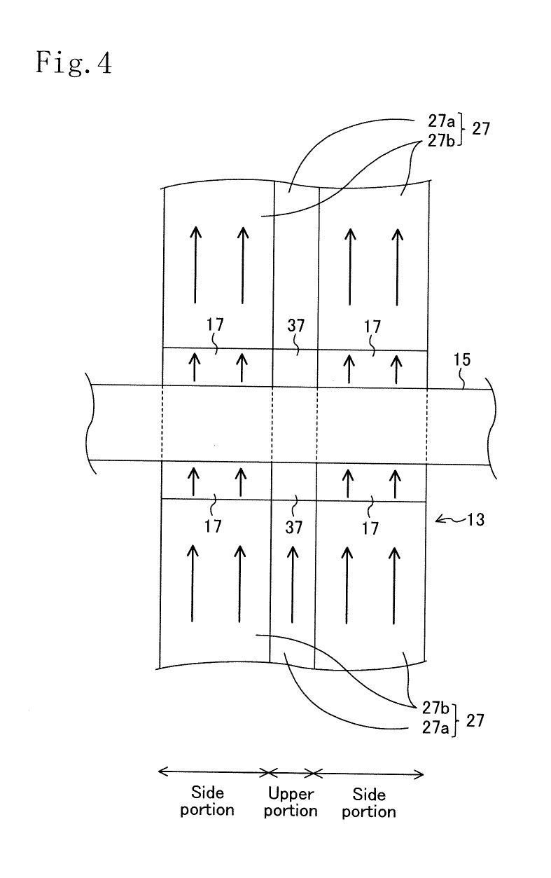

FIG. 4 schematically shows current (indicated by arrows) flowing in an ON state of gate with side surfaces of a fin-shaped semiconductor region developed on the same plane (an imaginary plane) as the upper surface of the fin-shaped semiconductor region in the semiconductor device of this embodiment. As shown in FIG. 4, in the semiconductor device of this embodiment, the presence of the resistance region 37 in the upper portion of the fin-shaped semiconductor region 13 prevents the upper portion of the fin-shaped semiconductor region 13 from functioning as channel even in an ON state of gate. In FIG. 4, components of the semiconductor device also shown in FIGS. 1(a) through 1(e) are denoted by the same reference numerals.

In this embodiment, when the implantation dose of the extension regions 17 formed in the side portions of the fin-shaped semiconductor region 13 is larger than or equal to about 80% (preferably, 90%) of that of the resistance region 37 formed in the upper portion of the fin-shaped semiconductor region 13, transistor characteristics can be remarkably improved, as compared to conventional techniques. This is because of the following reason: In this embodiment, an amorphous region formed in the upper portion of the fin-shaped semiconductor region 13 at least partially remains in an amorphous state after heat treatment for impurity activation, thus increasing the resistivity of the upper portion (i.e., the resistance region 37) of the fin-shaped semiconductor region 13. The ion implantation doses of the upper and side portions of the fin-shaped semiconductor region 13 are preferably made equal to each other wherever possible. More preferably, the implantation dose of the side portions of the fin-shaped semiconductor region 13 is larger than that of the upper portion of the fin-shaped semiconductor region 13. Then, it is possible to reduce the increased resistance of the upper portion of the fin-shaped semiconductor region 13, which has to be increased by leaving the amorphous region after heat treatment. As a result, transistor characteristics can be remarkably improved with ease, as compared to conventional techniques.

In this embodiment, the source/drain regions 27 (i.e., the impurity regions 27a and 28b) are formed in the upper and side portions of the fin-shaped semiconductor region 13 located at the sides of the insulating sidewall spacers 16 opposite the gate electrode 15. Alternatively, in the same manner as for the extension regions 17, a resistance region may be provided in an upper portion of the fin-shaped semiconductor region 13 so that the source/drain regions 27 are formed only in side portions of the fin-shaped semiconductor region 13. In this case, the implantation dose of the impurity regions formed as the source/drain regions 27 in the side portions of the fin-shaped semiconductor region 13 is also preferably larger than or equal to about 80% (more preferably, 90%) of that of the impurity region formed as the resistance region in the upper portion of the fin-shaped semiconductor region 13. Then, transistor characteristics can be remarkably improved with ease, as compared to conventional techniques, as described above.

In this embodiment, a plasma doping method is employed for forming the extension regions 17 and the source/drain regions 27. Alternatively, an ion implantation method may be employed. In the case of an ion implantation method, it is not easier to reduce the implantation dose of the side portions of the fin-shaped semiconductor region than to reduce the implantation dose of the upper portion of the fin-shaped semiconductor region. However, when an amorphous region formed in the upper portion of the fin-shaped semiconductor region is made thicker than amorphous regions formed in the side portions of the fin-shaped semiconductor region by adjusting ion implantation conditions, advantages similar to those of this embodiment can be obtained.

In this embodiment, conditions for both extension implantation and heat treatment for impurity activation are adjusted in order to form the extension regions 17 in side portions of the fin-shaped semiconductor region 13 and to form, in an upper portion of the fin-shaped semiconductor region 13, the resistance region 37 having a higher resistivity than the extension regions 17. Alternatively, conditions for only one of extension implantation and heat treatment for impurity activation may be adjusted.

In this embodiment, unlike a conventional double-gate FinFET, no hard mask is provided between the upper surface of the fin-shaped semiconductor region and the gate electrode. Alternatively, a hard mask may be provided between the upper surface of the fin-shaped semiconductor region 13 and the gate electrode 15 (precisely, the gate insulating film 14).

### Amorphous Region Formation And Crystal Recovery In Fin-Shaped Semiconductor Region

Formation of an amorphous region by extension implantation in a fin-shaped semiconductor region and crystal recovery by subsequent heat treatment in this embodiment are now described.

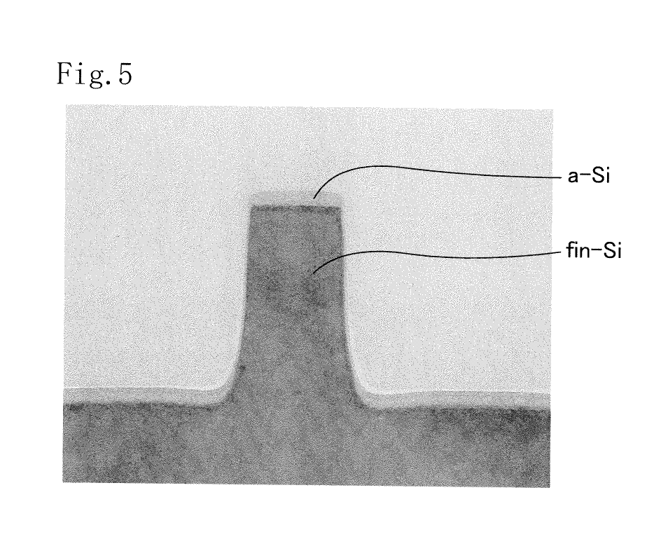

FIG. 5 is a TEM (transmission electron microscope) photograph immediately after implantation of an impurity in a fin-shaped semiconductor region (denoted as fin-Si in FIG. 5) by extension implantation (specifically, plasma doping) of this embodiment. As shown in FIG. 5, an amorphous region (a-Si in FIG. 5) in an upper portion of the fin-shaped semiconductor region is thicker than amorphous regions in side portions of the fin-shaped semiconductor region. It is noted that the thickness of an amorphous region is determined depending on the depth of ions entering a semiconductor region (a silicon region) i.e., implantation energy (a bias voltage in terms of a parameter of a plasma doping condition). Since ions are incident on the substrate at an angle almost perpendicular to the principle plane of the substrate, the ions are incident on the upper surface of the fin-shaped semiconductor region at a large angle (basically, about 85 to 95 degrees), and are incident on each side surface of the fin-shaped semiconductor region at a very small angle (smaller than or equal to about 5 degrees). Suppose ions incident on the upper and side surfaces of the fin-shaped semiconductor region have the same implantation energy. Then, ions are incident on the upper surface of the fin-shaped semiconductor region at a large angle, and thus travel to a deep level in the upper portion of the fin-shaped semiconductor region, thus damaging silicon crystal. Consequently, a thick amorphous region is formed. On the other hand, ions are incident on the side surface of the fin-shaped semiconductor region at a very small angle, and thus travel only to a shallow level in the side portion of the fin-shaped semiconductor region, thus damaging only silicon crystal at the shallow level. Consequently, only a very thin amorphous region is formed. In addition, the thickness of the amorphous region in the upper portion of the fin-shaped semiconductor region increases as the implantation energy is increased. However, even when the implantation energy is increased, the thickness of the amorphous region in the side portion of the fin-shaped semiconductor region increases to a smaller extent than that of the amorphous region in the upper portion of the fin-shaped semiconductor region. Strictly speaking, the traveling distance of entering ions in the side portion of the fin-shaped semiconductor region is considered to increase as the implantation energy increases. However, because of the influence of the very small incident angle of entering ions described above, the influence of the implantation energy on the thickness of the amorphous region in the side portion of the fin-shaped semiconductor region is substantially negligible.

Now, description is given on a process for crystal recovery by performing heat treatment on amorphous regions which are formed with plasma doping as described above to be thick in an upper portion of a fin-shaped semiconductor region and thin in a side portion of the fin-shaped semiconductor region.

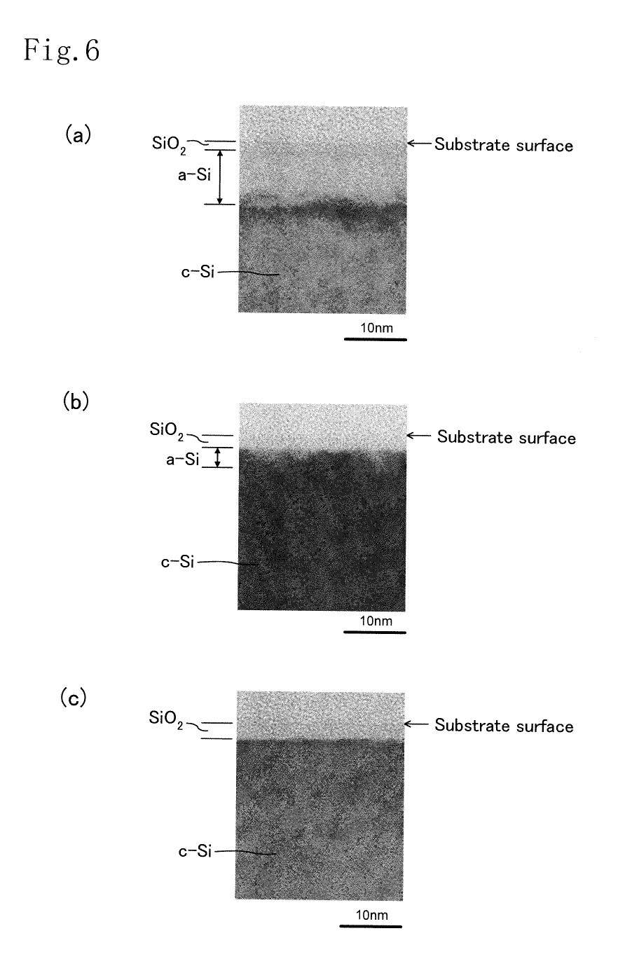

FIG. 6(a) is a TEM photograph immediately after plasma doping on a flat surface portion of a semiconductor substrate corresponding to an upper portion of a fin-shaped semiconductor region. FIG. 6(b) is a TEM photograph after heat treatment performed at 925 degrees centigrade with spike RTA after the plasma doping. FIG. 6(c) is a TEM photograph after heat treatment performed at 1000 degrees centigrade with spike RTA after the plasma doping. In FIGS. 6(a) through 6(c), a-Si is an amorphous region, and c-Si is a crystal region.

As shown in FIGS. 6(a) through 6(c), when heat treatment is performed on an amorphous region formed by plasma doping as in this embodiment, crystal recovery occurs from inside the substrate to the surface thereof. Accordingly, it is found that adjustment of conditions for plasma doping and annealing allows crystal recovery of an amorphous region to occur in a deep portion of a semiconductor region and also allows an amorphous region in a surface portion of the semiconductor region to remain without change.

As described above, combination of two features:
(1) immediately after impurity implantation by plasma doping, a thick amorphous region is formed in an upper portion of a fin-shaped semiconductor region, and a thin amorphous region is formed in a side portion of the fin-shaped semiconductor region; and
(2) in heat treatment for impurity activation, crystal recovery occurs from inside the semiconductor region to the surface thereof,
   respectively described with reference to FIG. 5 and FIGS. 6(a) through 6(c), i.e., adjustment of conditions for plasma doping and annealing, achieves a structure in which crystal recovery of the amorphous region occurs in the side portion of the fin-shaped semiconductor region after heat treatment and at least a surface portion of the amorphous region in the upper portion of the fin-shaped semiconductor region remains in an amorphous state. Accordingly, the resistivity of the side portion of the fin-shaped semiconductor region decreases, whereas the resistivity of the upper portion of the fin-shaped semiconductor region increases. As a result, a double-gate FinFET according to this disclosure in which the resistivity in the side portion of the fin-shaped semiconductor region is lower than that of the upper portion of the fin-shaped semiconductor region can be implemented.

### Conditions For Plasma Doping And Annealing For Achieving Advantages of This Disclosure

Conditions for plasma doping and annealing for achieving advantages of this disclosure in this embodiment are now described.

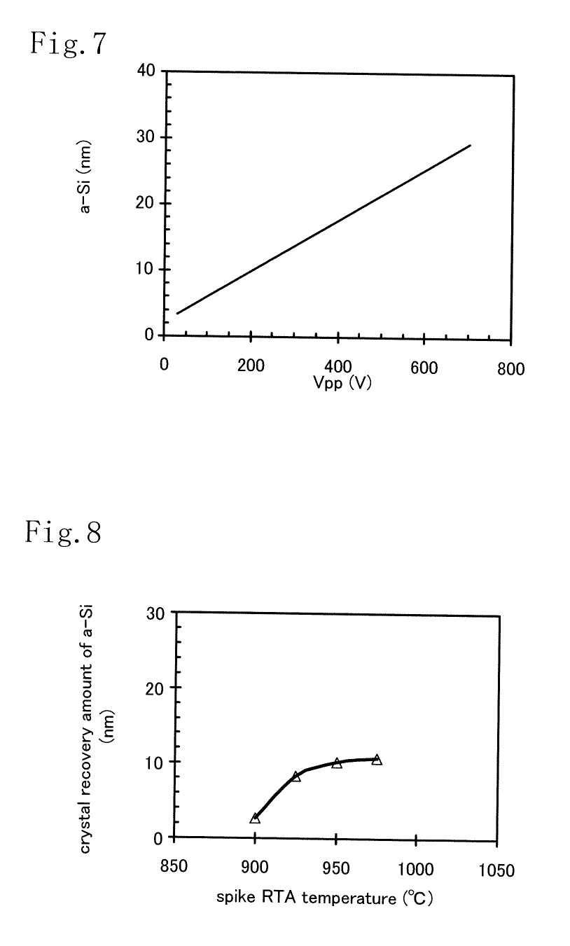

FIG. 7 is shows a relationship between a bias voltage (Vpp) and the thickness of an amorphous region (a-Si) in a case where plasma doping using gas mixture of B₂H₆ and He is performed for 60 seconds. As shown in FIG. 7, when Vpp is set at 50 V, a portion of a semiconductor region (a silicon region) to a depth of about 4 nm from the upper surface of the semiconductor region is changed to amorphous silicon. That is, an amorphous region with a thickness of about 4 nm is formed in an upper portion of a fin-shaped semiconductor region. When Vpp is set at 175 V, an amorphous region with a thickness of about 9 nm is formed in an upper portion of the fin-shaped semiconductor region. When Vpp is set at 250 V, an amorphous region with a thickness of about 12 nm is formed in an upper portion of the fin-shaped semiconductor region. Although not shown, only a very thin amorphous region is formed in a side portion of the fin-shaped semiconductor region. Specifically, only an amorphous region with a thickness smaller than or equal to about 2.5 nm, which may slightly change depending on plasma doping conditions, is formed. This is due to the fact that the angle of incidence of ions in plasma on the principle plane of the substrate (i.e., the tilt angle with respect to the normal of the principle plane of the substrate) is close to zero (but not zero, i.e., a very small angle less than about 5 degrees). Specifically, the angle of incidence of ions on the upper surface of the fin-shaped semiconductor region is very small (less than about 5 degrees as described above), whereas the angle of incidence of ions on the side surface of the fin-shaped semiconductor region is very large because the side surface of the fin-shaped semiconductor region forms an angle of 90 degrees with the upper surface thereof. This allows ions to reach a deep level in an upper portion of the fin-shaped semiconductor region, but to reach only a shallow level in a side portion of the fin-shaped semiconductor region because of tilted incidence of ions. Consequently, an amorphous region with a thickness depending on the Vpp level is formed in the upper portion of the fin-shaped semiconductor region, whereas only a thin amorphous region independent of the Vpp level is formed in the side portion of the fin-shaped semiconductor region. This phenomenon is employed in this embodiment.

FIG. 8 shows a relationship between a spike RTA temperature and the thickness of amorphous silicon which has recovered to crystal silicon (i.e., the crystal recovery amount of a-Si). As shown in FIG. 8, in the case of performing spike RTA at 900 degrees centigrade, amorphous silicon recovers to crystal silicon only to a thickness of about 2.7 nm from the interface between crystal silicon and amorphous silicon toward the surface of a silicon region. On the other hand, the crystal recovery amount of a-Si is about 8.3 nm in the case of performing spike RTA at 925 degrees centigrade, and the crystal recovery amount of a-Si is about 10.8 nm in the case of performing spike RTA at 975 degrees centigrade.

Based on the characteristics shown in FIGS. 7 and 8, the inventors derived the following examples of Vpp during plasma doping and the temperature of spike RTA for providing advantages of this disclosure.

### Condition Example 1

Plasma doping with boron is performed at Vpp higher than or equal to 50 V, and heat treatment with spike RTA is performed at a temperature lower than or equal to 900 degrees centigrade to electrically activate boron. In this case, immediately after plasma doping, an amorphous region with a thickness larger than or equal to about 4 nm is formed in an upper portion of a fin-shaped semiconductor region, and an amorphous region with a thickness smaller than or equal to about 2.5 nm is formed in a side portion of the fin-shaped semiconductor region. The heat treatment in this case causes an amorphous region with a thickness smaller than or equal to about 2.7 nm to recover to crystal silicon. Accordingly, the amorphous region in the side portion of the fin-shaped semiconductor region almost completely recovers to crystal silicon, whereas the amorphous region remains in the upper portion of the fin-shaped semiconductor region to a depth larger than or equal to about 1.3 nm from the upper surface of the fin-shaped semiconductor region. This means that electric resistance of the side portion of the fin-shaped semiconductor region decreases and that electric resistance of the upper portion of the fin-shaped semiconductor region increases. In this manner, by setting Vpp during plasma doping at 50 V or more and performing heat treatment with spike RTA at 900 degrees centigrade or less, resistance distribution suitable for the double-gate FinFET of this disclosure can be obtained.

### Condition Example 2

Plasma doping with boron is performed at Vpp higher than or equal to 175 V, and heat treatment with spike RTA is performed at a temperature lower than or equal to 925 degrees centigrade to electrically activate boron. In this case, immediately after plasma doping, an amorphous region with a thickness larger than or equal to about 9 nm is formed in an upper portion of a fin-shaped semiconductor region, and an amorphous region with a thickness smaller than or equal to about 2.5 nm is formed in a side portion of the fin-shaped semiconductor region. The heat treatment in this case causes an amorphous region with a thickness smaller than or equal to about 8.3 nm to recover to crystal silicon. Accordingly, the amorphous region in the side portion of the fin-shaped semiconductor region almost completely recovers to crystal silicon, whereas the amorphous region remains in the upper portion of the fin-shaped semiconductor region to a depth larger than or equal to about 0.7 nm from the upper surface of the fin-shaped semiconductor region. This means that electric resistance of the side portion of the fin-shaped semiconductor region decreases and that electric resistance of the upper portion of the fin-shaped semiconductor region increases. In this manner, by setting Vpp during plasma doping at 175 V or more and performing heat treatment with spike RTA at 925 degrees centigrade or less, resistance distribution suitable for the double-gate FinFET of this disclosure can be obtained.

### Condition Example 3 (More Preferred Condition Example)

Plasma doping with boron is performed at Vpp higher than or equal to 250 V, and heat treatment with spike RTA is performed at a temperature lower than or equal to 975 degrees centigrade to electrically activate boron. In this case, immediately after plasma doping, an amorphous region with a thickness larger than or equal to about 12 nm is formed in an upper portion of a fin-shaped semiconductor region, and an amorphous region with a thickness smaller than or equal to 2.5 nm is formed in a side portion of the fin-shaped semiconductor region. The heat treatment in this case causes an amorphous region with a thickness smaller than or equal to about 10.8 nm to recover to crystal silicon. Accordingly, the amorphous region in the side portion of the fin-shaped semiconductor region almost completely recovers to crystal silicon, whereas the amorphous region remains in the upper portion of the fin-shaped semiconductor region to a depth larger than or equal to about 1.2 nm from the upper surface of the fin-shaped semiconductor region. This means that electric resistance of the side portion of the fin-shaped semiconductor region decreases and that electric resistance of the upper portion of the fin-shaped semiconductor region increases. In this manner, by setting Vpp during plasma doping at 250 V or more and performing heat treatment with spike RTA at 975 degrees centigrade or less, resistance distribution suitable for the double-gate FinFET of this disclosure can be obtained. In addition, to increase the activation yield of boron to a practical level, the temperature of spike RTA is set as high as possible (preferably, 950 degrees centigrade or more) as in this condition example. Then, not only resistance distribution suitable for the double-gate FinFET of this disclosure but also extension regions having a sheet resistance which is low at a practical level can be achieved.

### Specific Structure of Semiconductor Device Obtained In First Example Embodiment

Now, an example of a specific structure of a semiconductor device obtained by the fabrication method of this embodiment is described.

### Structure Example 1

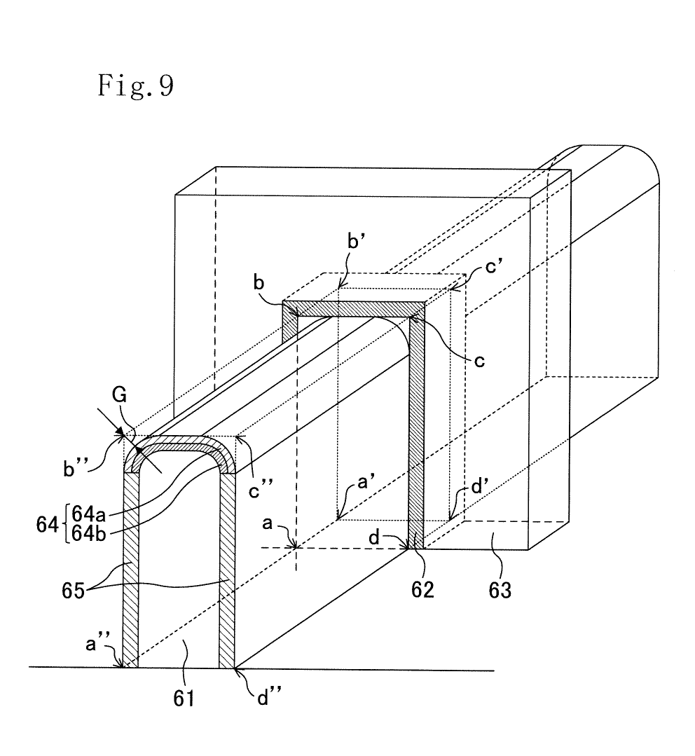

FIG. 9 is a perspective view schematically illustrating an example of a specific structure of a semiconductor device obtained by the fabrication method of this embodiment. Specifically, the semiconductor device illustrated in FIG. 9 has a structure in which a gate electrode is fog lied to extend across a fin-shaped semiconductor region having a substantially right-angled upper corner before plasma doping with a gate insulating film interposed between the gate electrode and the fin-shaped semiconductor region. More specifically, as illustrated in FIG. 9, a gate electrode 63 is formed to extend across a fin-shaped semiconductor region 61 including a resistance region 64 in its upper portion and extension regions 65 in its side portions, with a gate insulating film 62 interposed between the gate electrode 63 and the fin-shaped semiconductor region 61. The resistance region 64 includes an upper amorphous region 64a and a lower impurity region 64b. In FIG. 9, a, b, c, and d denote source-side corners of the inner wall of the gate insulating film 62 in a pommel horse shape, and a″, b″, c″, and d″ denote corners respectively shifted in parallel from the corners a, b, c, and d to the end facet of the fin-shaped semiconductor region 61 at the source side.

In general, sidewall spacers are formed on extension regions to protect the extension regions after extension implantation. The “end facet at the source side” can be the as a portion of a region covered with the sidewall spacer (not shown in FIG. 9) and located farthest from channel. On the other hand, a portion of the fin-shaped semiconductor region 61 on which no sidewall spacer material remains (i.e., a portion on which no sidewall spacer is eventually formed) is excluded from the “end facet at the source side” because upper corners of this portion can be etched under the influence of, for example, dry etching performed to form sidewall spacers after extension implantation, i.e., under the influence of factors except for plasma doping.

In the semiconductor device illustrated in FIG. 9, the height of the fin-shaped semiconductor region 61 is 10 nm to 500 nm, for example, the width of the fin-shaped semiconductor region 61 is 10 nm to 500 nm, for example, and the distance between adjacent fin-shaped semiconductor regions 61 is 20 nm to 500 nm. When this disclosure is applied to a semiconductor device including such fine fin-shaped semiconductor regions 61, this semiconductor device may exhibit a feature in which the distance G between the corner b″ and the resistance region 64 (an upper portion of the fin), i.e., the distance G between the corner c″ and the resistance region 64 (the upper portion of the fin), is larger than zero and smaller than or equal to 10 nm, and a feature in which the resistivity of the extension regions 65 (side portions of the fin) is lower than that of the resistance region 64 (the upper portion of the fin). As a result, advantages of this disclosure can be achieved.

Suppose source-side corners of the inner wall of the gate insulating film 62 having a pommel horse shape are respectively a, b, c, and d, and their corresponding corners at the drain side are respectively a′, b′, c′, and d′. Then, the distance G between the corner b″ and the resistance region 64 (the upper portion of the fin) or the distance G between the corner c″ and the resistance region 64 (the upper portion of the fin) is the maximum distance between the resistance region 64 and one of a plane including a square a-a′-b′-b, a plane including a square b-b′-c′-c, and a plane including a square c-c′-d′-d. This maximum distance reflects the amount of chipping of an upper corner of the fin-shaped semiconductor region 61 by plasma doping. The feature in which the distance G between the corner b″ and the resistance region 64 (the upper portion of the fin), i.e., the distance G between the corner c″ and the resistance region 64 (the upper portion of the fin), is larger than zero and smaller than or equal to 10 nm is generally equivalent to a feature in which the radius r′ of curvature of an upper corner of the fin-shaped semiconductor region 61 in a region located outside the gate insulating film 62 (i.e., the radius of curvature after plasma doping) is greater than the radius r of curvature of an upper corner of the fin-shaped semiconductor region 61 in a region under the gate insulating film 62 (i.e., the radius of curvature before plasma doping), and is smaller than or equal to 2r.

### Structure Example 2

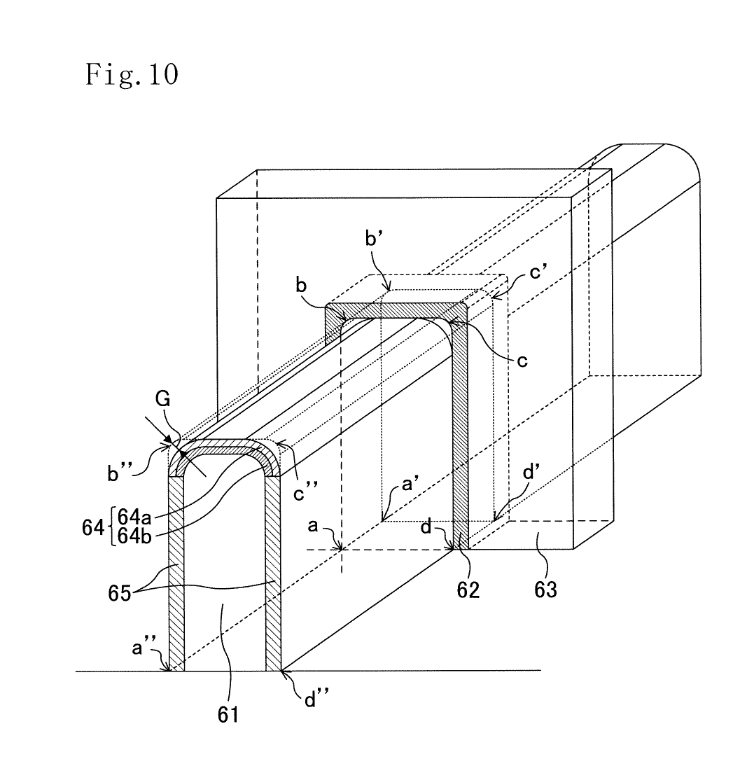

FIG. 10 is a perspective view schematically illustrating another example of the specific structure of the semiconductor device obtained by the fabrication method of this embodiment. Specifically, in the semiconductor device illustrated in FIG. 10, a fin-shaped semiconductor region is formed such that an upper corner has a certain degree of radius of curvature before formation of a gate electrode, and that the gate electrode is formed to extend across the fin-shaped semiconductor region with a gate insulating film interposed between the gate electrode and the fin-shaped semiconductor region. In FIG. 10, components also shown in FIG. 9 are denoted by the same reference numerals, and description thereof is omitted.

In application of this disclosure to a semiconductor device including a fin-shaped semiconductor region 61 as illustrated in FIG. 10, the semiconductor device also exhibits a feature in which the distance G between the corner b″ and the resistance region 64 (an upper portion of the fin), i.e., the distance G between the corner c″ and the resistance region 64 (the upper portion of the fin), is larger than zero and smaller than or equal to 10 nm, and a feature in which the resistivity of the extension regions 65 (side portions of the fin) is lower than that of the resistance region 64 (the upper portion of the fin). As a result, advantages of this disclosure can be achieved.

### Second Example Embodiment

Hereinafter, a semiconductor device and a method for fabricating a semiconductor device according to a second example embodiment of the present invention will be described with reference to the drawings.

The second example embodiment is different from the first example embodiment in that a resistance region 37 (precisely, an amorphous region) formed in an upper portion of a fin-shaped semiconductor region 13 contains germanium, for example, as a crystallization inhibitor.

Specifically, in this embodiment, the pressure during plasma doping is set to be lower than or equal to 0.6 Pa, and a p-type impurity (e.g., boron) is introduced into upper and side portions of the fin-shaped semiconductor region 13, for example, as in the first example embodiment. In addition, as a feature of the second example embodiment, germanium ions are implanted in the upper portions of the fin-shaped semiconductor region 13 in the direction perpendicular to the principle plane of the substrate with an ion implantation method. This makes the resistivity of side portions (i.e., extension regions 17) of the fin-shaped semiconductor region 13 lower than that of the upper portion (i.e., the resistance region 37) of the fin-shaped semiconductor region 13, while suppressing the amount of chipping of an upper corner (a fin corner) of the fin-shaped semiconductor region 13.

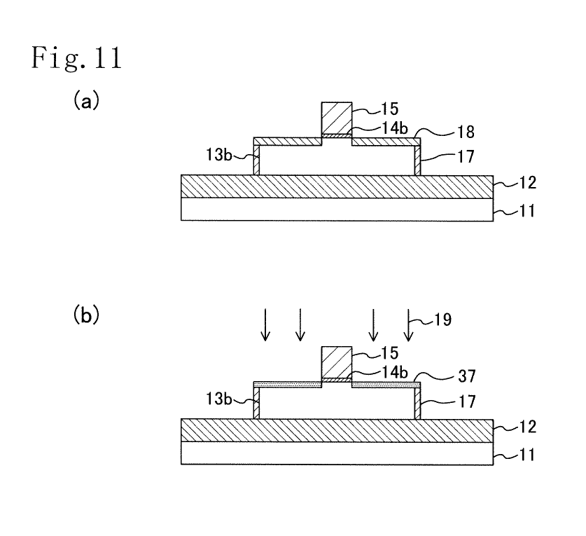

FIGS. 11(a) and 11(b) are cross-sectional views showing step by step a method for fabricating a semiconductor device according to this embodiment. FIGS. 11(a) and 11(b) correspond to the cross-sectional structure taken along line D-D in FIG. 1(a).

In this embodiment, first, a process similar to that of the first example embodiment shown in FIG. 2(a) is performed. Specifically, an SOI substrate in which a semiconductor layer having a thickness of 65 nm and made of silicon, for example, is provided over a supporting substrate 11 having a thickness of 775 micro meters and made of silicon, for example, with an insulating layer 12 having a thickness of 150 nm and made of silicon oxide, for example, interposed therebetween is prepared. Then, the semiconductor layer is patterned, thereby forming an n-type fin-shaped semiconductor region 13b to be an active region.

Next, a process similar to that of the first example embodiment shown in FIG. 2(b) is performed. Specifically, a gate insulating film 14 having a thickness of 2 nm and made of hafnium oxide, for example, is formed to cover the upper and side surfaces of the fin-shaped semiconductor region 13b. Thereafter, a polysilicon film 15A having a thickness of 20 nm, for example, is formed over the entire surface of the supporting substrate 11.

Then, as shown in FIG. 11(a), a resist pattern (not shown) is formed over the polysilicon film 15A to cover a gate electrode region with, for example, a double-patterning technique. Using this resist pattern as a mask, the polysilicon film 15A is etched, thereby forming a gate electrode 15 on the fin-shaped semiconductor region 13b. Thereafter, the resist pattern is removed. In this process, the gate insulating film 14 is also etched, thereby leaving a gate insulating film 14b under the gate electrode 15.

Then, using the gate electrode 15 as a mask, upper and side portions of the fin-shaped semiconductor region 13b are doped with a p-type impurity (e.g., boron) with a plasma doping method. In this manner, as shown in FIG. 11(a), p-type impurity regions to be extension regions 17 are formed in side portions of the fin-shaped semiconductor region 13b, whereas p-type impurity regions 18 are formed in upper portions of the fin-shaped semiconductor region 13b.

In this embodiment, the plasma doping condition in which the pressure during the plasma doping is set to be lower than or equal to 0.6 Pa is employed as described above. This makes the implantation dose of the side portions of the fin-shaped semiconductor region 13b larger than or equal to 80% of the implantation dose of the upper portions of the fin-shaped semiconductor region 13b. Specifically, the plasma doping condition is such that the material gas is B₂H₆ (diborane) diluted with He (helium), the B₂H₆ concentration in the material gas is 0.5% by mass, the total flow rate of the material gas is 100 cm³/min (standard condition), the chamber pressure is 0.35 Pa, the source power (plasma-generating high-frequency power) is 500 W, the bias voltage (Vpp) is 250 V, and the plasma doping time is 60 seconds.

Then, as shown in FIG. 11(b), using the gate electrode 15 as a mask, germanium ions 19 are implanted in the fin-shaped semiconductor region 13b in the direction perpendicular to the principle plane of the substrate with an ion implantation method. Since germanium ions 19 travel straight, implantation of germanium ions 19 perpendicular to the principle plane of the substrate causes the germanium ions 19 to be incident only on the upper surface of the fm-shaped semiconductor region 13b. Consequently, only upper portions (i.e., p-type impurity regions 18) of the fin-shaped semiconductor region 13b are in an amorphous state to form a resistance region 37.

Specific ion implantation conditions are, for example, that ion species is germanium, the angle of incidence of ions is perpendicular to the principle plane of the substrate, the dose is about 2×14 cm², and the implantation depth is greater than that of boron implanted in the upper portions of the fin-shaped semiconductor region 13b in the extension implantation described above. In this manner, thick amorphous regions are formed in upper portions of the fin-shaped semiconductor region 13b, and crystal recovery is less likely to occur in these amorphous regions in subsequent heat treatment for impurity activation. Consequently, the resistivity of the side portions (i.e., the extension regions 17) of the fin-shaped semiconductor region 13b is lower than that of the upper portions (i.e., the resistance region 37) of the fin-shaped semiconductor region 13b. As a result, transistor characteristics can be remarkably improved, as compared to conventional techniques.

Subsequently, although not shown, ions of an impurity are implanted in the fin-shaped semiconductor region 13b with the gate electrode 15 used as a mask, thereby forming n-type pocket regions.

Thereafter, a process similar to that of the first example embodiment shown in FIG. 2(d) is performed. Specifically, insulating sidewall spacers 16 are formed on the side surfaces of the gate electrode 15, and then p-type impurity regions 27a and 27b constituting source/drain regions 27 are respectively formed in upper and side portions of the fin-shaped semiconductor region 13b located outside the insulating sidewall spacers 16.

Then, to electrically activate the impurities introduced into the extension region 17 and the source/drain regions 27 with heat treatment, spike RTA, for example, is performed at about 1000 degrees centigrade. In this heat treatment, the heat treatment temperature and the heat treatment time are adjusted such that crystal recovery of an amorphous region occurs in side portions (i.e., the extension regions 17) of the fin-shaped semiconductor region 13b and that amorphous regions in upper portions (i.e., the resistance region 37) of the fin-shaped semiconductor region 13b at least partially remain in an amorphous state. In this manner, the resistivity of the extension regions 17 is reduced to a value lower than the resistivity of the resistance region 37 in the complete semiconductor device, thus obtaining desired transistor characteristics. In the case of employing spike RTA or millisecond annealing as a specific heat treatment method, the heat treatment time is substantially fixed, and thus the thermal budget is substantially based on the setting of the heat treatment temperature.

In this embodiment, in addition to advantages similar to those of the first example embodiment, the following advantages are obtained. Specifically, introduction of the crystallization inhibitor (e.g., germanium) into the resistance region 37 formed in an upper portion of the fin-shaped semiconductor region 13 increases a process window (i.e., a margin in conditions for, for example, plasma doping or heat treatment for impurity activation) for making the resistivity of the resistance region 37 higher than that of the extension regions 17. In other words, a process window for leaving a thicker amorphous region in the resistance region 37 is increased. Accordingly, a desired resistance region 37 can be more reliably and easily formed.

In this embodiment, extension implantation and implantation of the crystallization inhibitor are performed in this order between formation of the gate electrode 15 and formation of the insulating sidewall spacers 16. Alternatively, implantation of the crystallization inhibitor may be performed before extension implantation.

In addition, germanium is introduced as the crystallization inhibitor in this embodiment. Alternatively, argon, fluorine, or nitrogen, for example, may be introduced, or an impurity, such as arsenic, of a conductivity type opposite to that of the extension regions 17 may be introduced.

### Third Example Embodiment

Hereinafter, a semiconductor device and a method for fabricating a semiconductor device according to a third example embodiment of the present invention will be described with reference to the drawings.

The third example embodiment is different from the first example embodiment in that a resistance region 37 (precisely, an amorphous region) formed in an upper portion of a fin-shaped semiconductor region 13 contains an impurity, such as arsenic, of a conductivity type (i.e., n-type) opposite to the conductivity type of p-type extension regions 17.

Specifically, in this embodiment, the pressure during plasma doping is set to be lower than or equal to 0.6 Pa, and a p-type impurity (e.g., boron) is introduced into upper and side portions of the fin-shaped semiconductor region 13, as in the first example embodiment. In addition, as a feature of the third example embodiment, arsenic ions are implanted in an upper portion of the fin-shaped semiconductor region 13 in the direction perpendicular to the principle plane of the substrate with an ion implantation method. This makes the resistivity of side portions (i.e., extension regions 17) of the fin-shaped semiconductor region 13 lower than that of the upper portion (i.e., the resistance region 37) of the fin-shaped semiconductor region 13, while suppressing the amount of chipping of an upper corner (a fin corner) of the fin-shaped semiconductor region 13.

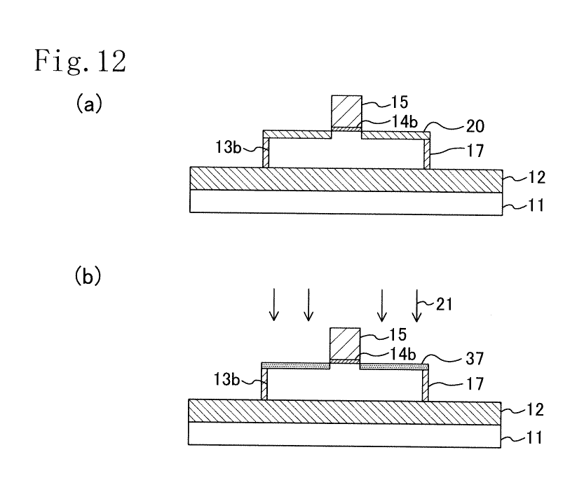

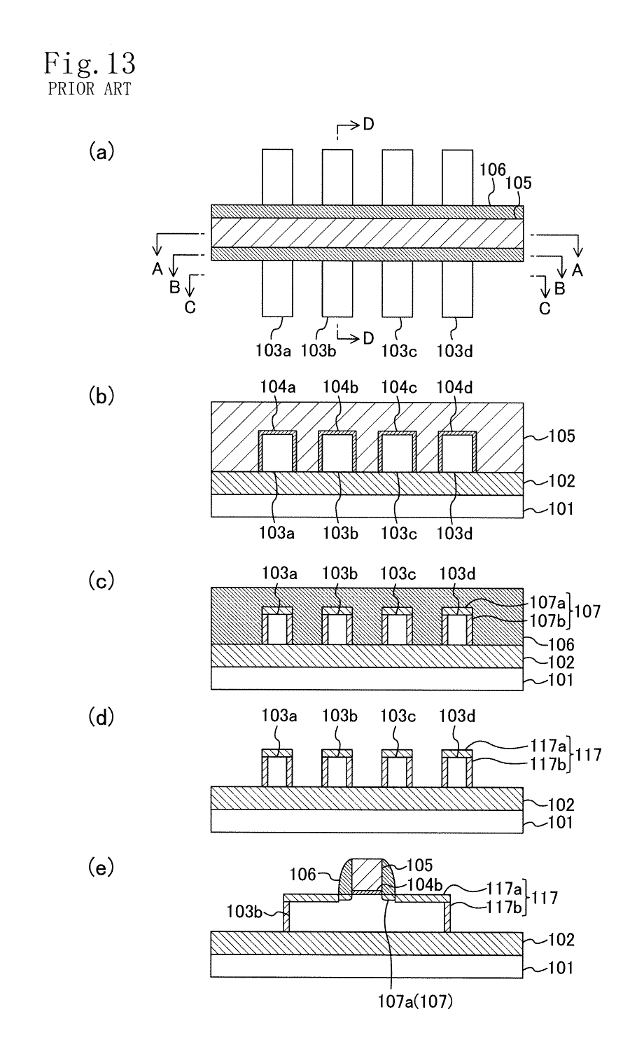

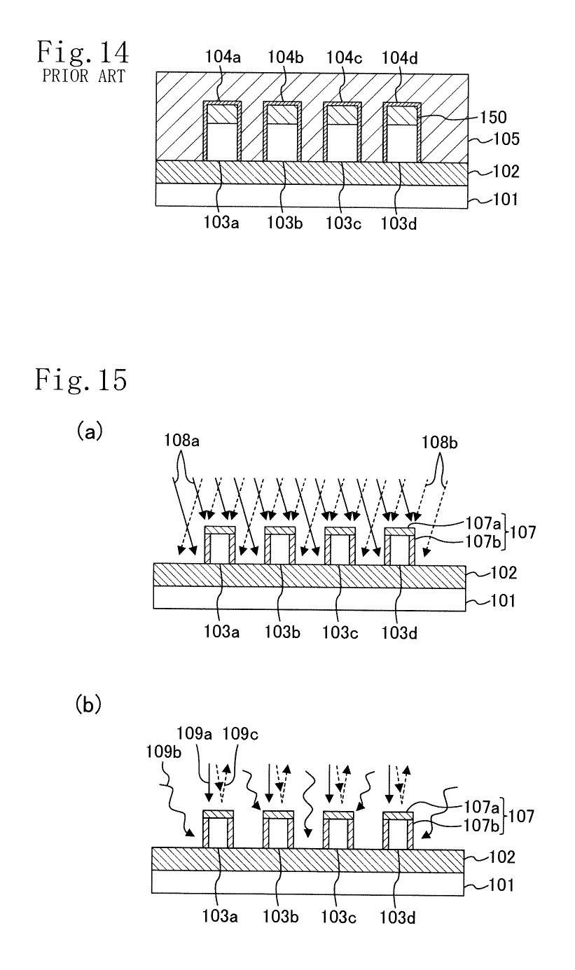

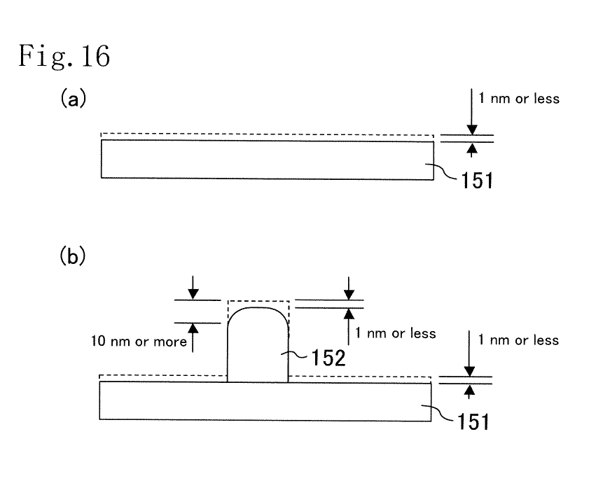

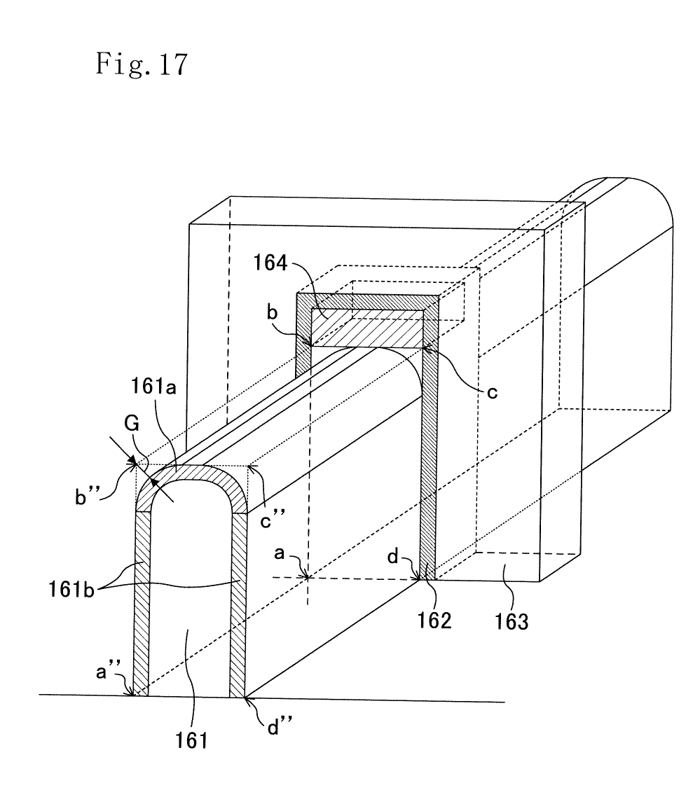

FIGS. 12(a) and 12(b) are cross-sectional views showing step by step a method for fabricating a semiconductor device according to this embodiment. FIGS. 12(a) and 12(b) correspond to the cross-sectional structure taken along line D-D in FIG. 1(a).

In this embodiment, first, a process similar to that of the first example embodiment shown in FIG. 2(a) is performed. Specifically, an SOI substrate in which a semiconductor layer having a thickness of 65 nm and made of silicon, for example, is provided over a supporting substrate 11 having a thickness of 775 micro meters and made of silicon, for example, with an insulating layer 12 having a thickness of 150 nm and made of silicon oxide, for example, interposed therebetween is prepared. Then, the semiconductor layer is patterned, thereby forming an n-type fin-shaped semiconductor region 13b to be an active region.

Next, a process similar to that of the first example embodiment shown in FIG. 2(b) is performed. Specifically, a gate insulating film 14 having a thickness of 2 nm and made of hafnium oxide, for example, is formed to cover the upper and side surfaces of the fin-shaped semiconductor region 13b. Thereafter, a polysilicon film 15A having a thickness of 20 nm, for example, is formed over the entire surface of the supporting substrate 11.

Then, as shown in FIG. 12(a), a resist pattern (not shown) is formed over the polysilicon film 15A to cover a gate electrode region with, for example, a double-patterning technique. Using this resist pattern as a mask, the polysilicon film 15A is etched, thereby forming a gate electrode 15 on the fin-shaped semiconductor region 13b. Thereafter, the resist pattern is removed. In this process, the gate insulating film 14 is also etched, thereby leaving a gate insulating film 14b under the gate electrode 15.

Then, using the gate electrode 15 as a mask, upper and side portions of the fin-shaped semiconductor region 13b are doped with a p-type impurity (e.g., boron) with a plasma doping method. In this manner, as shown in FIG. 12(a), p-type impurity regions to be extension regions 17 are formed in side portions of the fin-shaped semiconductor region 13b, whereas p-type impurity regions 20 are formed in upper portions of the fin-shaped semiconductor region 13b.

In this embodiment, the plasma doping condition in which the pressure during the plasma doping is set to be lower than or equal to 0.6 Pa is employed as described above. This makes the implantation dose of the side portions of the fin-shaped semiconductor region 13b larger than or equal to 80% of the implantation dose of the upper portions of the fin-shaped semiconductor region 13b.

In this embodiment, the bias voltage (Vpp) during plasma doping is lower (e.g., 250 V) than that in the first example embodiment, thereby reducing the thickness of amorphous regions formed in the upper portions (i.e., the p-type impurity regions 20) of the fin-shaped semiconductor region 13b, as compared to the first example embodiment. In this manner, in this embodiment, crystal recovery occurs not only in amorphous regions in the side portions (i.e., the extension regions 17) of the fin-shaped semiconductor region 13b but also in amorphous regions in the upper portions (i.e., the p-type impurity regions 20) of the fin-shaped semiconductor region 13b, after subsequent heat treatment for impurity activation.

Specifically, the plasma doping condition is such that the material gas is B₂H₆ (diborane) diluted with He (helium), the B₂H₆ concentration in the material gas is 0.5% by mass, the total flow rate of the material gas is 100 cm³/min (standard condition), the chamber pressure is 0.35 Pa, the source power (plasma-generating high-frequency power) is 500 W, the bias voltage (Vpp) is 250 V, and the plasma doping time is 60 seconds.

Then, as shown in FIG. 12(b), using the gate electrode 15 as a mask, arsenic ions 21 are implanted, as an impurity (an n-type impurity) of a conductivity different from the impurity (i.e., the p-type impurity) used in the extension implantation described above, in the fin-shaped semiconductor region 13b in the direction perpendicular to the principle plane of the substrate with an ion implantation method. Since arsenic ions 21 travel straight, implantation of arsenic ions 21 perpendicular to the principle plane of the substrate causes the arsenic ions 21 to be incident only on the upper surface of the fin-shaped semiconductor region 13b. Consequently, the polarity of electrical characteristics of only the upper portions (i.e., the p-type impurity regions 20) of the fin-shaped semiconductor region 13b is neutralized, thereby forming a resistance region 37.

Specific ion implantation conditions are, for example, that ion species is arsenic (As), the angle of incidence of ions is perpendicular to the principle plane of the substrate, the dose is equal to that of boron implanted in the upper portions of the fin-shaped semiconductor region 13b in the extension implantation described above, the implantation depth is equal to that of boron implanted in the upper portions of the fin-shaped semiconductor region 13b in the extension implantation described above, and implantation energy is 0.8 keV. In this manner, ions of an impurity (an n-type impurity) of a conductivity type different from that of the impurity (a p-type impurity) used in extension implantation are implanted in upper portions (i.e., the p-type impurity regions 20) of the fin-shaped semiconductor region 13b, and thus the polarity of electrical characteristics of the upper portions of the fin-shaped semiconductor region 13b is neutralized, thereby forming the resistance region 37. Accordingly, the resistivity of side portions (i.e., the extension regions 17) of the fin-shaped semiconductor region 13b is lower than that of the upper portions (i.e., the resistance region 37) of the fin-shaped semiconductor region 13b after subsequent heat treatment for impurity activation. As a result, transistor characteristics can be remarkably improved, as compared to conventional techniques.

Subsequently, although not shown, ions of an impurity are implanted in the fin-shaped semiconductor region 13b with the gate electrode 15 used as a mask, thereby forming n-type pocket regions.

Thereafter, a process similar to that of the first example embodiment shown in FIG. 2(d) is performed. Specifically insulating sidewall spacers 16 are formed on the side surfaces of the gate electrode 15, and then p-type impurity regions 27a and 27b constituting source/drain regions 27 are respectively formed in upper and side portions of the fin-shaped semiconductor region 13b located outside the insulating sidewall spacers 16.

Then, to electrically activate the impurities introduced into the extension regions 17 and the source/drain regions 27 with heat treatment, spike RTA, for example, is performed at about 1000 degrees centigrade.

In this embodiment, in addition to advantages similar to those of the first example embodiment, the following advantages are obtained. Specifically, introduction of the impurity (e.g., arsenic) of a conductivity type opposite to that of the extension regions 17 into the resistance region 37 formed in upper portions of the fin-shaped semiconductor region 13 increases a process window (i.e., a margin in conditions for, for example, plasma doping or heat treatment for impurity activation) for making the resistivity of the resistance region 37 higher than that of the extension regions 17. Accordingly, a desired resistance region 37 can be more reliably and easily formed.

In this embodiment, extension implantation and implantation of an impurity of the opposite conductivity type are performed in this order between formation of the gate electrode 15 and formation of the insulating sidewall spacers 16. Alternatively, implantation of the impurity of the opposite conductivity type may be performed before extension implantation. Otherwise, heat treatment for activating the impurity introduced into the extension regions 17 may be performed before implantation of the impurity of the opposite conductivity type. In this case, after implantation of the impurity of the opposite conductivity type, heat treatment for activating the impurity of the opposite conductivity type is preferably performed.

In this embodiment, arsenic is introduced as an impurity of an opposite conductivity type to that of the extension regions 17. Of course, the impurity of an opposite conductivity type is not limited to arsenic.

In this embodiment, an impurity of an opposite conductivity type to that of the extension regions 17 is introduced into the resistance region 37 in order to make the resistivity of the resistance region 37 higher than that of the extension regions 17. Alternatively, a desired resistance region 37 may be formed by at least etching and removing at least a surface portion having a relatively high concentration of a p-type impurity in the p-type impurity regions 20 (i.e., upper portions of the fin-shaped semiconductor region 13b) to be the resistance region 37.

### INDUSTRIAL APPLICABILITY

This disclosure relates to semiconductor devices and methods for fabricating semiconductor devices, and is useful for obtaining desired characteristics especially of a double-gate semiconductor device with a three-dimensional structure including a fin-shaped semiconductor region on a substrate.

### DESCRIPTION OF REFERENCE CHARACTERS

11 Supporting Substrate

12 Insulating Layer

13 (13a to 13d) Fin-shaped Semiconductor Region

14 (14a to 14d) Gate Insulating Film

15 Gate Electrode

15A Polysilicon Film

16 Insulating Sidewall Spacer

17 Extension Region

18 P-type Impurity Region

19 Germanium Ions

20 P-type Impurity Region

21 Arsenic Ions

27 Source/Drain Regions

27a Impurity Region

27b Impurity Region

37 High-resistance Region

61 Fin-Shaped Semiconductor Region

62 Gate Insulating Film

63 Gate Electrode

64 Resistance Region

64a Amorphous Region

64b Impurity Region

65 Extension Region

1. A semiconductor device, comprising:
a fin-shaped semiconductor region formed on a substrate and including an extension region in each side portion of the fin-shaped semiconductor region;
a gate electrode formed to extend across the fin-shaped semiconductor region and to be adjacent to the extension regions; and
a resistance region formed in an upper portion of the fin-shaped semiconductor region adjacent to the gate electrode, the resistance region having a resistivity higher than that of the extension regions.

2. The semiconductor device of claim 1, further comprising a gate insulating film, the gate insulating film being formed on the fin-shaped semiconductor region so as to be disposed between the gate electrode and the fin-shaped semiconductor region.

3. The semiconductor device of claim 1, further comprising insulating sidewall spacers formed so as to cover a side surface of the gate electrode, the resistance region being disposed beneath the insulating sidewall spacers.

4. The semiconductor device of claim 1, wherein the resistance region is formed in substantially the upper portion of the fin-shaped semiconductor region except a portion of the fin-shaped semiconductor region located beneath the gate electrode.

5. The semiconductor device of claim 1, wherein the resistance region is formed in the upper portion of the fin-shaped semiconductor region that extends laterally from the gate electrode.

6. The semiconductor device of claim 1, wherein the resistance region is formed in substantially the upper portion of the fin-shaped semiconductor region that extends laterally from the gate electrode.

7. The semiconductor device of claim 1, wherein a channel in which current flows during an ON state is formed in the side portions of the fin-shaped semiconductor region covered with the gate electrode.

8. The semiconductor device of claim 7, wherein the resistance region is configured to limit a current flow in the upper portion of the fin-shaped semiconductor region during the ON state.

9. The semiconductor device of claim 7, wherein a larger amount of current flows in the channel than that in the resistance region during the ON state.

10. The semiconductor device of claim 1, wherein the upper portion of the fin-shaped semiconductor region does not function as a channel during operation.

11. The semiconductor device of claim 1, wherein current flow occurring during an ON state is substantially uniform in the side portions of the fin-shaped semiconductor region covered with the gate electrode.

12. The semiconductor device of claim 1, wherein the resistance region includes an amorphous region.

13. The semiconductor device of claim 12, wherein the amorphous region contains a crystallization inhibitor.

14. The semiconductor device of claim 13, wherein the crystallization inhibitor is one of germanium, argon, fluorine, and nitrogen.

15. The semiconductor device of claim 1, wherein the resistance region is doped with an impurity of a conductivity type opposite to a conductivity type of the extension region.

16. The semiconductor device of claim 1, wherein the fin-shaped semiconductor region is provided on an insulating layer formed on the substrate.

17. The semiconductor device of claim 1, wherein an insulating sidewall spacer is formed to cover the extension region, the resistance region, and each side surface of the gate electrode, and
source/drain regions are formed in at least side portions of the fin-shaped semiconductor each located outside the insulating sidewall spacer away from the gate electrode.

18. The semiconductor device of claim 1, wherein the fin-shaped semiconductor region has a side surface whose height is greater than a width in a gate width direction of an upper surface of the fin-shaped semiconductor region.

19. A method for fabricating a semiconductor device, the method comprising the steps of:
(a) forming a fin-shaped semiconductor region on a substrate;
(b) forming a gate electrode across the fin-shaped semiconductor region;
(c) introducing an impurity into an upper portion of the fin-shaped semiconductor region and side portions of the fin-shaped semiconductor region so as to form a first impurity region in the upper portion of the fin-shaped semiconductor region and a second impurity region in each of the side portions of the fin-shaped semiconductor region; and
(d) electrically activating the impurity introduced into the first impurity region and the second impurity region, wherein
a process condition for at least one of steps (c) and (d) is selected such that the first impurity region is in at least a partially amorphous state.

20. The method of claim 19, wherein the gate electrode is utilized as a mask when introducing the impurity.

21. The method of claim 19, wherein the impurity is electrically activated by utilizing a heat treatment.

22. The method of claim 19, wherein a resistivity of the first impurity region in the partially amorphous state is higher than that of the second impurity region.

23. The method of claim 19, wherein step (c) utilizes a plasma doping process, and a bias voltage during plasma doping is adjusted such that a first amorphous region formed in an upper portion of the fin-shaped semiconductor region has a thickness larger than that of a second amorphous region formed in each side portion of the fin-shaped semiconductor region.

24. The method of claim 23, wherein in step (d), a temperature of the heat treatment is selected such that crystal recovery occurs in the second amorphous region, and that the first amorphous region remains in at least a partially amorphous state.

25. The method of claim 19, further comprising the step of introducing a crystallization inhibitor into an upper portion of the fin-shaped semiconductor region, between steps (b) and (c) or between steps (c) and (d).

26. The method of claim 25, wherein the crystallization inhibitor is one of germanium, argon, fluorine, and nitrogen.

27. The method of claim 19, further comprising the step of forming an insulating layer on the substrate, the fin-shaped semiconductor region being formed on the insulating layer.

28. The method of claim 19, wherein the fin-shaped semiconductor region has a side surface perpendicular to an upper surface of the fin-shaped semiconductor region.

29. A method for fabricating a semiconductor device, the method comprising the steps of:
(a) forming a fin-shaped semiconductor region on a substrate;
(b) forming a gate electrode across the fin-shaped semiconductor region;
(c) introducing an impurity of a first conductivity type into an upper portion of the fin-shaped semiconductor region and side portions of the fin-shaped semiconductor region so as to form a first impurity region in the upper portion of the fin-shaped semiconductor region and a second impurity region in each of the side portions of the fin-shaped semiconductor region;
(d) electrically activating the impurity of the first conductivity type introduced into the first impurity region and the second impurity region; and
(e) introducing an impurity of a second conductivity type opposite to the first conductivity type into an upper portion of the fin-shaped semiconductor region, after step (b).

30. The method of claim 29, wherein the gate electrode is utilized as a mask when introducing the impurity of the first conductivity type and when introducing the impurity of the second conductivity type.

31. The method of claim 29, wherein the impurity of the first conductivity type is electrically activated by utilizing a heat treatment.

32. The method of claim 29, further comprising the step of forming an insulating layer on the substrate, the fin-shaped semiconductor region being formed on the insulating layer.

33. The method of claim 29, wherein the fin-shaped semiconductor region has a side surface perpendicular to an upper surface of the fin-shaped semiconductor region.

34. A method for fabricating a semiconductor device, the method comprising the steps of:
forming a fin-shaped semiconductor region on a substrate;
forming a gate electrode which extends across the fin-shaped semiconductor region;
forming an extension region in each side portion of the fin-shaped semiconductor region adjacent to the gate electrode, and
forming a resistance region in an upper portion of the fin-shaped semiconductor region adjacent to the gate electrode, the resistance region having a resistivity higher than that of the extension region.

35. The method for fabricating a semiconductor device of claim 34, further comprising the step of forming a gate insulating film on the fin-shaped semiconductor region such that the gate insulating film is disposed between the gate electrode and the fin-shaped semiconductor region.

36. The method for fabricating a semiconductor device of claim 34, further comprising the step of forming insulating sidewall spacers so as to cover a side surface of the gate electrode, the resistance region being disposed beneath the insulating sidewall spacers.

37. The method for fabricating a semiconductor device of claim 34, wherein the resistance region is formed in substantially the upper portion of the fin-shaped semiconductor region except a portion of the fin-shaped semiconductor region located beneath the gate electrode.

38. The method for fabricating a semiconductor device of claim 34, wherein the step of forming a resistance region includes forming the resistance region so as to be disposed in the upper portion of the fin-shaped semiconductor region that extends laterally from the gate electrode.

39. The method for fabricating a semiconductor device of claim 34, wherein the step of forming a resistance region includes forming the resistance region so as to be disposed in substantially the upper portion of the fin-shaped semiconductor region that extends laterally from the gate electrode.

40. The method for fabricating a semiconductor device of claim 34, wherein the resistance region includes an amorphous region.

41. The method for fabricating a semiconductor device of claim 40, wherein the amorphous region contains a crystallization inhibitor.

42. The method for fabricating a semiconductor device of claim 41, wherein the crystallization inhibitor is one of germanium, argon, fluorine, and nitrogen.
